(19) United States
(12) Patent Application Publication
(10) Pub. No.: US 2024/0107677 A1
(43) Pub. Date: Mar. 28, 2024

(54) ELECTRONIC CIRCUIT BOARD, BASE MEMBER, ELECTRONIC EQUIPMENT, ELECTRONIC EQUIPMENT MANUFACTURING METHOD, AND ELECTRONIC CIRCUIT BOARD MANUFACTURING METHOD

(71) Applicants: SONY GROUP CORPORATION, TOKYO (JP); SONY SEMICONDUCTOR SOLUTIONS CORPORATION, KANAGAWA (JP)

(72) Inventors: HIIZU OHTORII; HIROSHI MORITA, KANAGAWA (JP); YUSUKE OYAMA; EIJI OTANI; KEN KIKUCHI

(21) Appl. No.: 17/754,819

(22) PCT Filed: Oct. 22, 2020
(86) PCT No.: PCT/JP2020/039704

§ 371 Date: Apr. 13, 2022

(30) Foreign Application Priority Data
Oct. 23, 2019 (JP) 2019-192611

(51) Int. Cl. H05K 1/18; H05K 1/02

(52) U.S. Cl. CPC H05K 1/189; H05K 1/028; H05K 2201/10121; H05K 2201/10151

(57) ABSTRACT

The present technology relates to an electronic circuit board, a base member, electronic equipment, an electronic equipment manufacturing method and an electronic circuit board manufacturing method that make it possible to mount an electronic circuit board easily on a curved surface, for example. An electronic circuit board has a deformable wiring board having a plurality of areas that is long in one direction and is formed to be partially continuous with each other, and the plurality of areas of the wiring board is provided with deformable plate-like plate members that are more rigid than the wiring board. For example, the present technology can be applied to an electronic circuit board on which various devices are mounted.

### TECHNICAL FIELD

The present technology relates to an electronic circuit board, a base member, electronic equipment, an electronic equipment manufacturing method, and an electronic circuit board manufacturing method, and in particular relates to an electronic circuit board, a base member, electronic equipment, an electronic equipment manufacturing method, and an electronic circuit board manufacturing method that make it possible to mount an electronic circuit board easily on a curved surface, for example.

### BACKGROUND ART

As one of methods for mounting wires and devices on a curved surface, for example, there is a method that uses a stretchable resin film (see NPL 1, for example). In addition, there is a method that uses the MID (Molded Interconnect Device) technology (see NPL 2, for example).

### CITATION LIST

### Non Patent Literature

### [NPL 1]

“Panasonic Develops an Elastic Stretchable Resin Film—Provides an Insulation Material, a Transparent Electrode Material and an Electrically Conductive Paste for Wires,” [online], Dec. 25, 2015, [Retrieved on Aug. 24, 2020], the Internet <URL: https://news.panasonic.com/jp/topics/141979.html>

### [NPL 2]

“3D Packaging Device MIPTEC,” [online], [Retrieved on Aug. 24, 2020], the Internet <URL: https://www3.panasonic.biz/ac/j/tech/mid/miptec/index.jsp>

### SUMMARY

### Technical Problems

However, the methods mentioned above increase the costs for manufacturing of modules because the methods require special materials, manufacturing methods, and manufacturing apparatuses.

In addition, the methods mentioned above require apparatuses that support three-dimensional mounting for mounting of devices, for example, fluxing or solder printing apparatuses, mounters, reflow apparatuses and the like, and this likewise creates a risk of cost increase of the manufacturing of modules.

The present technology has been made in view of such a situation, and makes it possible to mount an electronic circuit board easily on a curved surface.

### Solution to Problems

An electronic circuit board of the present technology is an electronic circuit board including a deformable wiring board having a plurality of areas that is long in one direction and is formed to be partially continuous with each other, and a deformable plate-like plate member that is provided in the plurality of areas, and is more rigid than the wiring board.

In the electronic circuit board of the present technology, the deformable wiring board has the plurality of areas that is long in the one direction and is formed to be partially continuous with each other, and the deformable plate-like plate member that is more rigid than the wiring board is provided in the plurality of areas.

A base member of the present technology is a base member including a curved surface on which a positioning structure for positioning the electronic circuit board of the present technology is formed and the electronic circuit board is to be attached.

In the base member of the present technology, the positioning structure is formed on the curved surface on which the electronic circuit board of the present technology is to be attached.

Electronic equipment of the present technology is electronic equipment including the electronic circuit board of the present technology and the base member of the present technology to which the electronic circuit board is attached.

In the electronic equipment of the present technology, the electronic circuit board of the present technology is attached to the base member of the present technology.

An electronic equipment manufacturing method of the present technology is an electronic equipment manufacturing method including sandwiching and fixing end sections of the plate member of the electronic circuit board of the present technology by using jigs, pressing the electronic circuit board against a curved surface corresponding to a curved surface of a base member, and deforming the electronic circuit board, and attaching the electronic circuit board after the deformation to the curved surface of the base member.

In the electronic equipment manufacturing method of the present technology, the end sections of the plate member of the electronic circuit board of the present technology are sandwiched and fixed by using the jigs, the electronic circuit board is pressed against the curved surface corresponding to the curved surface of the base member, and the electronic circuit board is deformed. Then, the electronic circuit board after the deformation is attached to the curved surface of the base member.

An electronic circuit board manufacturing method of the present technology is an electronic circuit board manufacturing method including providing, in a plurality of areas that is long in one direction and is formed on a deformable wiring board such that the plurality of areas is partially continuous with each other, a deformable plate-like plate member that is more rigid than the wiring board.

In the electronic circuit board manufacturing method of the present technology, the deformable plate-like plate member that is more rigid than the wiring board is provided in the plurality of areas that is long in the one direction and is formed on the deformable wiring board such that the plurality of areas is partially continuous with each other.

The electronic equipment may be a discrete apparatus or may be an internal block included in one apparatus.

### BRIEF DESCRIPTION OF DRAWINGS

FIG. 1 is a cross-sectional view depicting a first configuration example of a light source chip 10 to which the present technology is applied.

FIG. 2 is a plan view depicting the first configuration example of the light source chip 10 to which the present technology is applied.

FIG. 3 is a plan view depicting a configuration example of a light-emitting board 11.

FIG. 4 is a cross-sectional view depicting a second configuration example of the light source chip 10.

FIG. 5 is a cross-sectional view depicting a third configuration example of the light source chip 10.

FIG. 6 is a cross-sectional view depicting a fourth configuration example of the light source chip 10.

FIG. 7 is a cross-sectional view depicting a fifth configuration example of the light source chip 10.

FIG. 8 is a cross-sectional view depicting a sixth configuration example of the light source chip 10.

FIG. 9 is a cross-sectional view for explaining a first alternative method for mounting the light source chip 10 on a flexible board 18.

FIG. 10 is a cross-sectional view for explaining a second alternative method for mounting the light source chip 10 on the flexible board 18.

FIG. 11 is a cross-sectional view for explaining a third alternative method for mounting the light source chip 10 on the flexible board 18.

FIG. 12 is a plan view depicting a first configuration example of a light source module to which the light source chips 10 are applied.

FIG. 13 is a plan view depicting a second configuration example of a light source module to which the light source chips 10 are applied.

FIG. 14 is a plan view depicting a third configuration example of a light source module to which the light source chips 10 are applied.

FIG. 15 is a plan view depicting a fourth configuration example of a light source module to which the light source chips 10 are applied.

FIG. 16 is a cross-sectional view depicting examples of deformation of the flexible board 18 having a reinforcing material 91 adhered thereon.

FIG. 17 is a figure depicting a first configuration example of a distance measurement module to which the light source chips 10 are applied.

FIG. 18 is a front view for explaining a configuration example of a base member 312.

FIG. 19 is a figure depicting a second configuration example of the distance measurement module to which the light source chips 10 are applied.

FIG. 20 is a figure for explaining control of a light source module 330 including a plurality of the light source chips 10 arranged therein.

FIG. 21 is a figure for explaining laser safety standards.

FIG. 22 is a block diagram depicting a fifth configuration example of a light source module to which the light source chips 10 are applied.

FIG. 23 is a plan view depicting a sixth configuration example of a light source module to which the light source chips 10 are applied.

FIG. 24 is a figure depicting an assembly example of a light source module 350.

FIG. 25 is a cross-sectional view depicting a configuration example of the light source module 350 assembled into a lantern-type light source module.

FIG. 26 is a cross-sectional view depicting a seventh configuration example of the light source chip to which the present technology is applied.

FIG. 27 is a perspective view depicting an overview of a seventh configuration example of a light source module to which the light source chips 10 are applied.

FIG. 28 is a cross-sectional view depicting the seventh configuration example of the light source module to which the light source chips 10 are applied.

FIG. 29 is a plan view depicting a configuration example of an electronic circuit board to which the present technology is applied.

FIG. 30 is a perspective view depicting the configuration example of the electronic circuit board to which the present technology is applied.

FIG. 31 is a plan view depicting alternative configuration examples of the electronic circuit board to which the present technology is applied.

FIG. 32 is a figure depicting a configuration example of primary-curved-surface curving jigs 450 for positionally aligning the reinforcing materials 91 of an electronic circuit board 410, as seen from above and from the front side thereof.

FIG. 33 is a plan view depicting a configuration example of a lower right part 460R and an upper right part 470R.

FIG. 34 is a figure depicting a state that pins 463 of the primary-curved-surface curving jigs 450 and positioning holes 411 of the electronic circuit board 410 are fit together, as seen from above and from the front side thereof.

FIG. 35 is a figure depicting a state that the reinforcing materials 91 of the electronic circuit board 410 are sandwiched between a lower left part 460L and an upper left part 470L and between the lower right part 460R and the upper right part 470R, as seen from above and from the front side thereof.

FIG. 36 is a figure depicting a configuration example of a primary-curved-surface model curved surface jig 510 that deforms the electronic circuit board 410, as seen from above and from the front side thereof.

FIG. 37 is a plan view and a cross-sectional view depicting a configuration example of the primary-curved-surface model curved surface jig 510.

FIG. 38 is a figure depicting a state before the electronic circuit board 410 having been attached to the primary-curved-surface curving jigs 450 is set on the primary-curved-surface model curved surface jig 510.

FIG. 39 is a figure depicting a state after the electronic circuit board 410 having been attached to the primary-curved-surface curving jigs 450 is set on the primary-curved-surface model curved surface jig 510.

FIG. 40 is a figure depicting the electronic circuit board 410 having been attached to the primary-curved-surface curving jigs 450 and having been detached from the primary-curved-surface model curved surface jig 510 after deformation of the electronic circuit board 410.

FIG. 41 is a figure depicting the electronic circuit board 410 having been detached from the primary-curved-surface curving jigs 450.

FIG. 42 is a perspective view depicting a configuration example of a secondary-curved-surface holding jig 520.

FIG. 43 is a figure depicting a state that the electronic circuit board 410 after the deformation has been attached to the secondary-curved-surface holding jig 520, as seen from above and from the front side thereof.

FIG. 44 is a figure depicting a state that a base member 610 has been attached to a secondary-curved-surface holding jig 590, as seen from above and from the front side thereof.

FIG. 45 is a figure depicting a state before the electronic circuit board 410 attached to the secondary-curved-surface holding jig 520 is attached to the base member 610 attached to the secondary-curved-surface holding jig 590.

FIG. 46 is a figure depicting a state that the electronic circuit board 410 attached to the secondary-curved-surface holding jig 520 has been attached to the base member 610 attached to the secondary-curved-surface holding jig 590, as seen from above and from the front side thereof.

FIG. 47 is a perspective view depicting a state that the electronic circuit board 410 attached to the secondary-curved-surface holding jig 520 has been attached to the base member 610 attached to the secondary-curved-surface holding jig 590.

FIG. 48 is a perspective view depicting a configuration example of a module 710 completed by attaching the electronic circuit board 410 to the base member 610.

FIG. 49 is a perspective view depicting an overview of a configuration example of a LiDAR to which the present technology is applied.

FIG. 50 is a figure depicting a configuration example of a transmitting section 811 and a receiving section 812.

FIG. 51 is a figure for explaining a positional relationship, in the LiDAR 810, between an imaging element 831 and the electronic circuit board 410 having the light source chips 10 mounted thereon.

FIG. 52 is a cross-sectional view depicting a configuration example of a light-receiving/emitting chip as a device that can be mounted on the electronic circuit board 410.

### DESCRIPTION OF EMBODIMENTS

### First Configuration Example of Light Source Chip 10

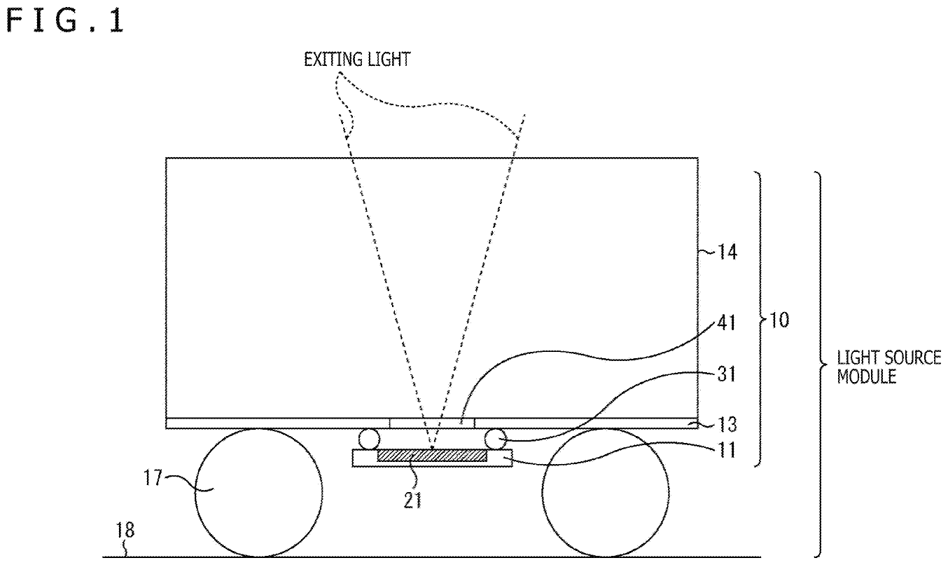

FIG. 1 is a cross-sectional view depicting a first configuration example of a light source chip 10 to which the present technology is applied.

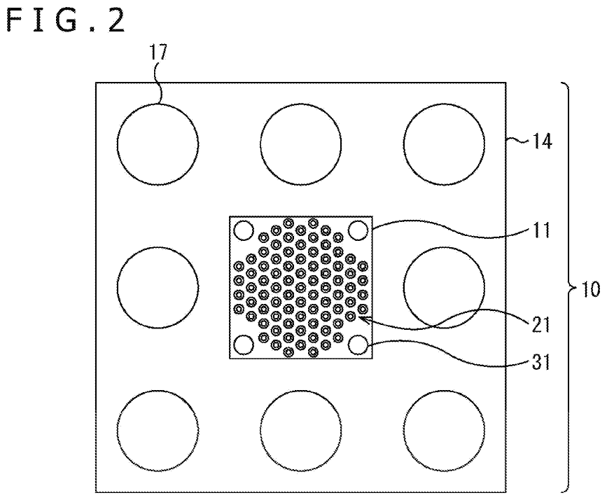

FIG. 2 is a plan view (top view) depicting the first configuration example of the light source chip 10.

Note that the light source chip 10 is depicted in FIG. 2 such that the inside of the light source chip 10 can be seen.

The light source chip 10 includes a light-emitting board 11, a circuit board 13, and a transmissive board 14, and has what is called a discrete integrated light source structure.

The light-emitting board 11 includes a light-emitting element 21 that emits light. The light-emitting element 21 includes, for example, a vertical cavity surface emitting laser (VCSEL, Vertical Cavity Surface Emitting LASER), and emits light with a wavelength of, for example, 905 nm (nano meters) at a pulse width of, for example, 6 ns (nano seconds).

For example, the circuit board 13 includes Si or GaAs, and the circuit board 13 has formed thereon various types of circuits that drive the light-emitting element 21.

The circuit board 13 has formed thereon various types of circuits that drive the light-emitting element 21 such as a light emission control section (LDD: laser diode driver), a serializer, or a deserializer which are not depicted, and the circuit board 13 drives the light-emitting element 21 and causes light to be emitted.

The transmissive board 14 transmits light emitted by the light-emitting element 21. The transmissive board 14 includes, for example, quartz. Note that the transmissive board 14 can include any material that transmits (the wavelength of) light emitted by the light-emitting element 21. For example, in a case that the light-emitting element 21 emits infrared light, the transmissive board 14 can include, for example, Si that transmits infrared light.

In the light source chip 10, the light-emitting board 11 is electrically connected to the circuit board 13 via first bumps (solder bumps) 31. The light-emitting board 11 is connected to the circuit board 13 such that light emitted by the light-emitting element 21 exits toward the circuit board 13. As depicted in FIG. 2, in the present embodiment, the light-emitting board 11 is connected to the circuit board 13 by four first bumps 31.

The circuit board 13 and the transmissive board 14 are joined, for example, by adhering to each other using an adhesive or the like.

In the present embodiment, a portion that is in the circuit board 13 and corresponds to the light-emitting element 21 (a portion to be irradiated with light emitted by the light-emitting element 21) is open, and an opening 41 is formed there. The opening 41 can be formed by, for example, dry etching or the like. Light emitted by the light-emitting element 21 enters the transmissive board 14 through the opening 41, is transmitted through, and exits from the transmissive board 14.

The light source chip 10 is configured such that the optical axis of (light emitted by) the light-emitting element 21 and the central axis of the opening 41 are arranged approximately coaxially.

Note that, in a case that the circuit board 13 includes a material that transmits light emitted by the light-emitting element 21 (a highly transmissive material), the circuit board 13 can be configured without the opening 41 being provided therethrough.

For example, the adoptable specifications of the light source chip 10 includes the light-emitting board 11: 50 μm (micro meters) thickness and 700 μm length of each side, the circuit board 13: 30 to 100 μm thickness, the transmissive board 14: 750 μm thickness and 1.3 mm (millimeters) length of each side, and the like. In this case, the size of the light source chip 10 as seen in a plan view (as seen from above) has a length of each side which is, for example, 1.3 mm. Here, for example, 60 W or the like can be adopted as the peak power of the light source chip 10.

The thus-configured light source chip 10 is included in a light source module by being mounted on a flexible board 18 as an organic board having, for example, two to four layers. The mounting of the light source chip 10 on the flexible board 18 can be performed by, for example, electrically connecting the circuit board 13 and the flexible board 18 via second bumps 17 such that the light-emitting board 11 is sandwiched therebetween.

As depicted in FIG. 2, in the present embodiment, the light source chip 10 is connected to the flexible board 18 via eight second bumps 17. The size of the second bumps 17 is, for example, pp 200 μm. In this case, the height (thickness) of the light source chip 10 including the second bumps 17 is approximately, for example, 0.84 mm.

Note that the light-emitting element 21 may include a typical high-output-power edge-emitting LD. However, in a case that it is difficult in terms of the structure to arrange an edge-emitting LD, a surface-emitting VCSEL can be applied as the light-emitting element 21. As a VCSEL, a front-side light-emitting type can be applied.

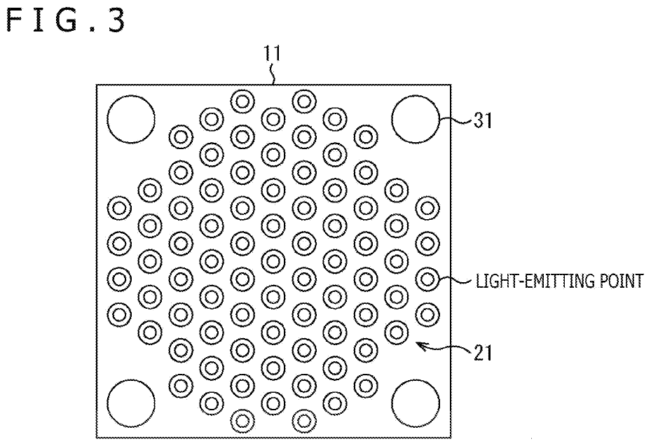

FIG. 3 is a plan view depicting a configuration example of the light-emitting board 11.

(The light-emitting element 21 of) the light-emitting board 11 has one or a plurality of light-emitting points. A light-emitting point has a mesa structure with a size of, for example, φ10 μm. Laser beams as light exit from the light-emitting points toward the nearer side of the figure. Note that, by contriving the mounting, the light-emitting board 11 can configure the light source chip 10 even if the light-emitting board 11 is a backside-emitting board that emits laser beams toward the back side of the figure.

For example, φ40 μm can be adopted as the size of the first bumps 31 that connect the light-emitting board 11 to the circuit board 13.

In addition, whereas the light-emitting board 11 has a plurality of light-emitting points in FIG. 3, the number of light-emitting points may be one.

Furthermore, in a case that a plurality of light-emitting points is provided in the light-emitting board 11, the plurality of light-emitting points can be provided at a pitch of, for example, 20 to 40 μm.

In addition, for example, 100 or 400 can be adopted as the number of light-emitting points. In a case that 400 light-emitting points are provided in the light-emitting board 11, the size of the light-emitting board 11 is approximately, for example, 700 μm in terms of the length of each side, as explained with reference to FIG. 1 and FIG. 2. In this case, the light-emitting board 11 can be regarded as a surface light source with a size which is approximately 700 μm in terms of the length of each side. In a case that 100 light-emitting points are provided in the light-emitting board 11, the size of the light-emitting board 11 is approximately, for example, 350 μm in terms of the length of each side. In this case, the light-emitting board 11 can be regarded as a surface light source with a size which is approximately 350 μm in terms of the length of each side.

### Second Configuration Example of Light Source Chip

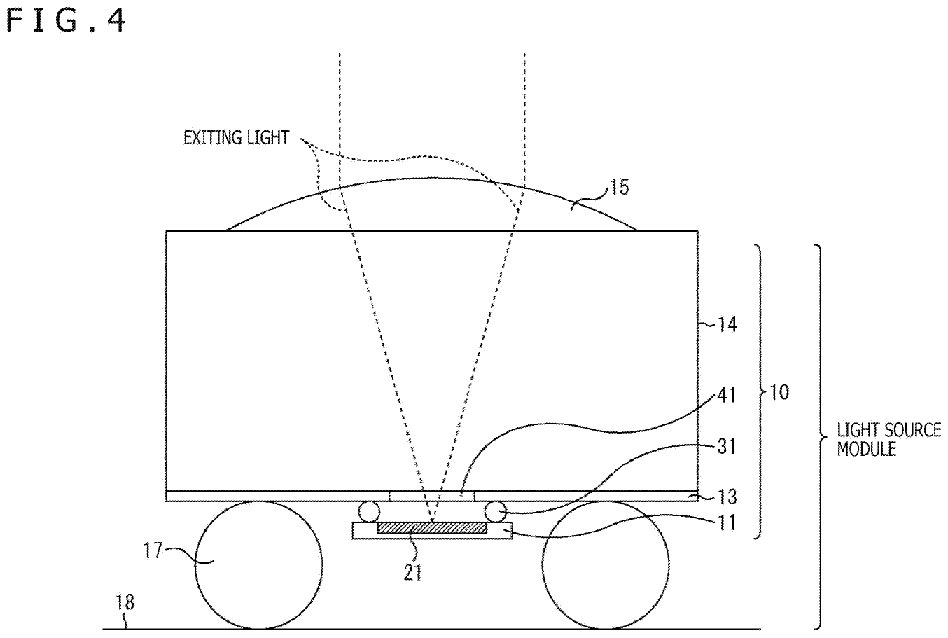

FIG. 4 is a cross-sectional view depicting a second configuration example of the light source chip 10.

Note that portions in the figure that have counterparts in the cases of FIG. 1 and FIG. 2 are given identical reference characters, and explanations thereof are omitted as appropriate below.

In FIG. 4, the light source chip 10 includes the light-emitting board 11, the circuit board 13, the transmissive board 14, and a lens 15.

Accordingly, the light source chip 10 in FIG. 4 is the same as in the cases of FIG. 1 and FIG. 2 in that the light source chip 10 has the light-emitting board 11, the circuit board 13, and the transmissive board 14. However, the light source chip 10 in FIG. 4 is different from the light source chip 10 in the cases of FIG. 1 and FIG. 2 in that the lens 15 is provided additionally.

In FIG. 4, the lens 15 is provided on a side opposite to the light-emitting-board-11 side of the transmissive board 14.

The lens 15 includes, for example, resin, acrylic, quartz, or the like, and is a collimate lens that converts light emitted by the light-emitting board 11 into (approximately) collimated light, for example, exiting light which is diffused light that spreads at 0.5 degrees.

The light source chip 10 is configured such that the optical axis of the lens 15, the optical axis of the light-emitting element 21, and the central axis of the opening 41 are arranged approximately coaxially.

### Third Configuration Example of Light Source Chip

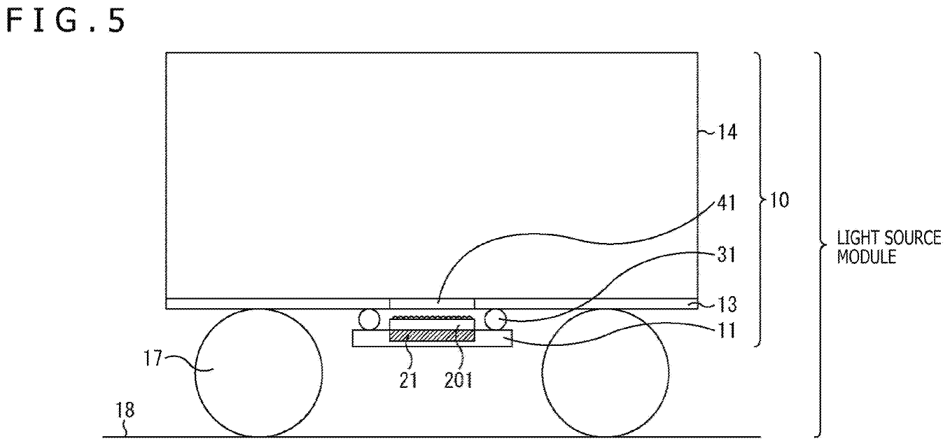

FIG. 5 is a cross-sectional view depicting a third configuration example of the light source chip 10.

Note that portions in the figure that have counterparts in the cases of FIG. 1 and FIG. 2 are given identical reference characters, and explanations thereof are omitted as appropriate below.

In FIG. 5, the light source chip 10 includes the light-emitting board 11, the circuit board 13, the transmissive board 14, and a lens array 201.

Accordingly, the light source chip 10 in FIG. 5 is the same as in the cases of FIG. 1 and FIG. 2 in that the light source chip 10 has the light-emitting board 11, the circuit board 13, and the transmissive board 14. However, the light source chip 10 in FIG. 5 is different from the light source chip 10 in the cases of FIG. 1 and FIG. 2 in that the lens array 201 is provided additionally.

The lens array 201 is provided on the light-emitting-board-11 side of the transmissive board 14. In FIG. 5, the lens array 201 is provided such that the lens array 201 directly contacts the light-emitting element 21 of the light-emitting board 11.

The lens array 201 includes, for example, microlenses similar to the lens 15 that are arranged on a flat plate similarly to the light-emitting points (FIG. 3) of the light-emitting board 11. Accordingly, the lens array 201 is provided with microlenses each for a light-emitting point of the light-emitting board 11.

The lens array 201 is provided on the light-emitting element 21 of the light-emitting board 11 such that the optical axes of (light emitted by) the light-emitting points of the light-emitting board 11 and the optical axes of the microlenses corresponding to the light-emitting points are arranged approximately coaxially.

In addition, the lens array 201 can be provided such that the microlenses provided on the flat plate are arranged on a side (the upper side in the figure) from which light from the light-emitting board 11 exits.

### Fourth Configuration Example of Light Source Chip

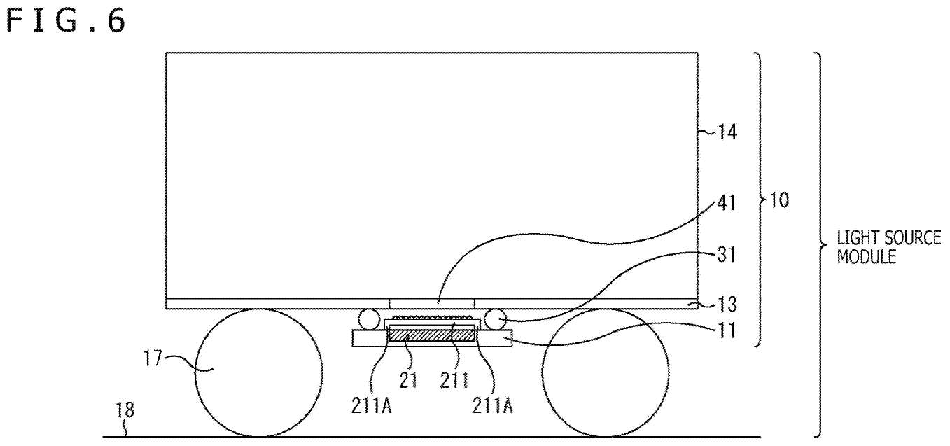

FIG. 6 is a cross-sectional view depicting a fourth configuration example of the light source chip 10.

Note that portions in the figure that have counterparts in the cases of FIG. 1 and FIG. 2 are given identical reference characters, and explanations thereof are omitted as appropriate below.

In FIG. 6, the light source chip 10 includes the light-emitting board 11, the circuit board 13, the transmissive board 14, and a lens array 211.

Accordingly, the light source chip 10 in FIG. 6 is the same as in the cases of FIG. 1 and FIG. 2 in that the light source chip 10 has the light-emitting board 11, the circuit board 13, and the transmissive board 14. However, the light source chip 10 in FIG. 6 is different from the light source chip 10 in the cases of FIG. 1 and FIG. 2 in that the lens array 211 is provided additionally.

Similarly to the lens array 201 in FIG. 5, the lens array 211 is provided on the light-emitting-board-11 side of the transmissive board 14.

Similarly to the lens array 201, the lens array 211 includes microlenses similar to the lens 15 that are arranged similarly to the light-emitting points of the light-emitting board 11.

Similarly to the lens array 201, the lens array 211 is provided on the light-emitting board 11 such that the optical axes of the light-emitting points of the light-emitting board 11 and the optical axes of the microlenses corresponding to the light-emitting points are arranged approximately coaxially.

It should be noted that the lens array 211 has, on the circumference (outer side), protrusions as leg portions 211A protruding in the optical axis direction of the microlenses, and is arranged on the light-emitting board 11 such that the leg portions 211A contact the light-emitting board 11. Thereby, the lens array 211 is supported on the light-emitting board 11 by the leg portions 211A.

Accordingly, in FIG. 6, a space (gap) is formed between the lens array 211 and the light-emitting element 21 of the light-emitting board 11, and the lens array 211 does not directly contact the light-emitting element 21 of the light-emitting board 11.

In this case, the stress of the lens array 211 can be prevented from being applied directly to the light-emitting element 21 of the light-emitting board 11.

For example, 10 to 50 μm can be adopted as the distance between the light-emitting element 21 of the light-emitting board 11 and the lenses of the lens array 211.

Note that, similarly to the lens array 201, the lens array 211 can be provided such that the microlenses provided on a flat plate are arranged on a side from which light from the light-emitting board 11 exits.

### Fifth Configuration Example of Light Source Chip

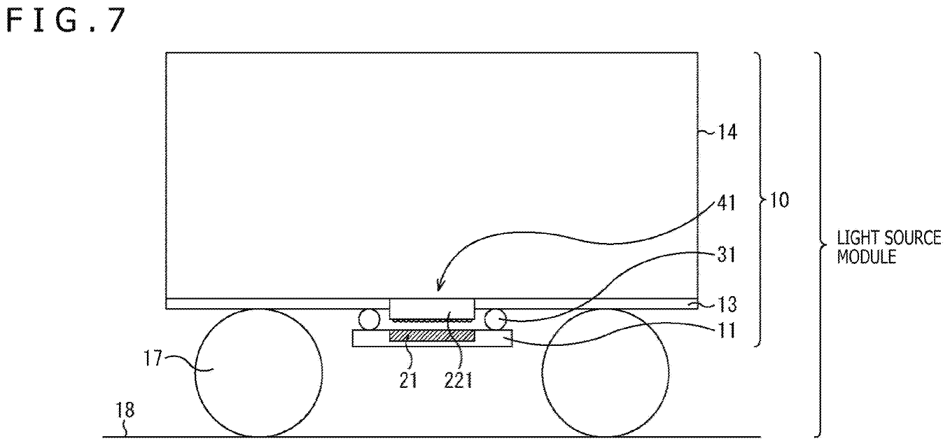

FIG. 7 is a cross-sectional view depicting a fifth configuration example of the light source chip 10.

Note that portions in the figure that have counterparts in the cases of FIG. 1 and FIG. 2 are given identical reference characters, and explanations thereof are omitted as appropriate below.

In FIG. 7, the light source chip 10 includes the light-emitting board 11, the circuit board 13, the transmissive board 14 and a lens array 221.

Accordingly, the light source chip 10 in FIG. 7 is the same as in the cases of FIG. 1 and FIG. 2 in that the light source chip 10 has the light-emitting board 11, the circuit board 13, and the transmissive board 14. It should be noted that the light source chip 10 in FIG. 7 is different from the light source chip 10 in the cases of FIG. 1 and FIG. 2 in that the lens array 221 is provided additionally.

Similarly to the lens array 201 in FIG. 5, the lens array 221 is provided on the light-emitting-board-11 side of the transmissive board 14.

Similarly to the lens array 201, the lens array 221 includes microlenses similar to the lens 15 that are arranged similarly to the light-emitting points of the light-emitting board 11.

Similarly to the lens array 201, the lens array 221 is provided on the light-emitting board 11 such that the optical axes of the light-emitting points of the light-emitting board 11 and the optical axes of the microlenses corresponding to the light-emitting points are arranged approximately coaxially.

It should be noted that the lens array 221 is supported by being fit into the opening 41 of the circuit board 13 and adhered to the transmissive board 14. In addition, the lens array 221 is supported by the transmissive board 14 such that a space is formed between the lens array 221 and the light-emitting element 21 of the light-emitting board 11.

In this case, the stress of the lens array 221 can be prevented from being applied directly to the light-emitting element 21 of the light-emitting board 11.

For example, 10 to 50 μm can be adopted as the distance between the light-emitting element 21 of the light-emitting board 11 and the lenses of the lens array 221.

Note that the lens array 221 can be provided such that the microlenses provided on a flat plate are arranged on a side (the lower side in the figure) from which light from the light-emitting board 11 enters.

### Sixth Configuration Example of Light Source Chip

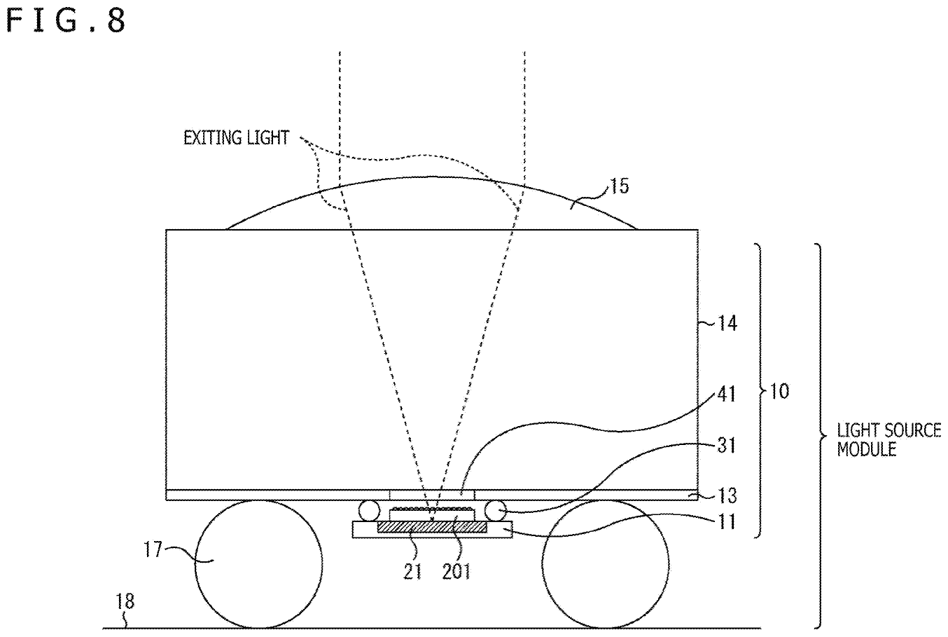

FIG. 8 is a cross-sectional view depicting a sixth configuration example of the light source chip 10.

Note that portions in the figure that have counterparts in the cases of FIG. 1 and FIG. 2 are given identical reference characters, and explanations thereof are omitted as appropriate below.

In FIG. 8, the light source chip 10 includes the light-emitting board 11, the circuit board 13, the transmissive board 14, the lens 15, and the lens array 201.

Accordingly, the light source chip 10 in FIG. 8 is the same as in the cases of FIG. 1 and FIG. 2 in that the light source chip 10 has the light-emitting board 11, the circuit board 13, and the transmissive board 14. However, the light source chip 10 in FIG. 8 is different from the light source chip 10 in the cases of FIG. 1 and FIG. 2 in that the lens 15 and the lens array 201 are provided additionally.

The lens 15 and the lens array 201 are explained with reference to FIG. 4 and FIG. 5, respectively, and therefore explanations thereof are omitted.

Note that, in the sixth configuration example of the light source chip 10, the lens array 211 in FIG. 6 or the lens array 221 in FIG. 7 can be provided instead of the lens array 201.

<Method of Mounting Light Source Chip 10 on Flexible Board 18>

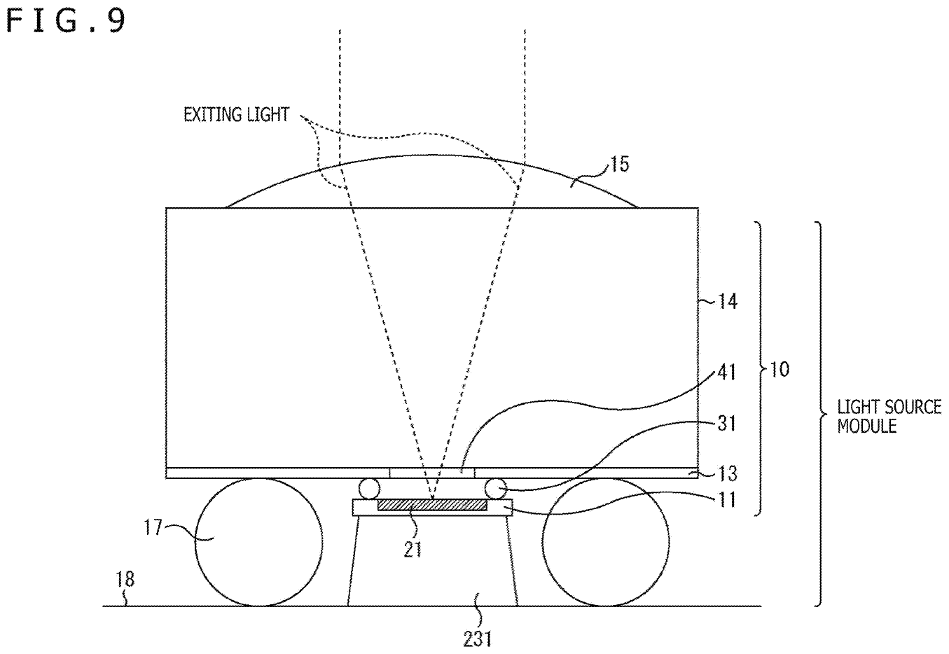

FIG. 9 is a cross-sectional view for explaining a first alternative method for mounting the light source chip 10 on the flexible board 18.

Other than the method of only electrically connecting the circuit board 13 and the flexible board 18 via the second bumps 17 such that the light-emitting board 11 is sandwiched therebetween as explained with reference to FIG. 1 and FIG. 2, alternative mounting methods can be adopted as the mounting method for the mounting of the light source chip 10 on the flexible board 18.

FIG. 9 is a cross-sectional view depicting the light source chip 10 mounted on the flexible board 18 by the first alternative mounting method.

Here, a surface emitting laser or the like can be used as the light-emitting element 21. The surface emitting laser or the like as the light-emitting element 21 has a low light emission duty (Duty) of 1% or lower, but can emit light with a high light intensity of approximately 15 W with 100 mesas (100 light-emitting points).

Because, if heat is confined in (the light-emitting board 11 having) the light-emitting element 21, heat resistance increases, and optical power lowers, it is desirable that the light source chip 10 has a high heat dissipation property.

By forming a heat dissipating body (heat dissipation pillar) 231 directly under the light-emitting board 11 and between the light-emitting board 11 and the flexible board 18, the heat dissipation property of the light source chip 10 can be enhanced. The heat dissipating body 231 can be formed by using, for example, solder or the like.

By being formed directly on copper wires of the flexible board 18, the heat dissipating body 231 can enhance heat dissipation effects.

For example, SAC solder which is similar to solder used for portions other than the heat dissipating body 231, such as the first bumps 31 and the second bumps 17 can be adopted as the solder as the heat dissipating body 231.

In addition, for example, Bi solder having a melting point lower than other solder used for portions other than the heat dissipating body 231, such as the first bumps 31 and the second bumps 17 can be adopted as the solder as the heat dissipating body 231.

In a case that solder having a melting point lower than other solder, such as the first bumps 31 or the second bumps 17, is adopted as the solder as the heat dissipating body 231, the solder as the heat dissipating body 231 is cured later than curing of the other solder at the time of reflowing when the light source chip 10 is mounted on the flexible board 18. Accordingly, at the time of the reflowing, the heat dissipating body 231 can reduce the (uneven) stress applied to the backside of the light-emitting board 11. Here, the backside of the light-emitting board 11 or the like is a surface opposite to a front side which is located on a side where light exits from the light source chip 10.

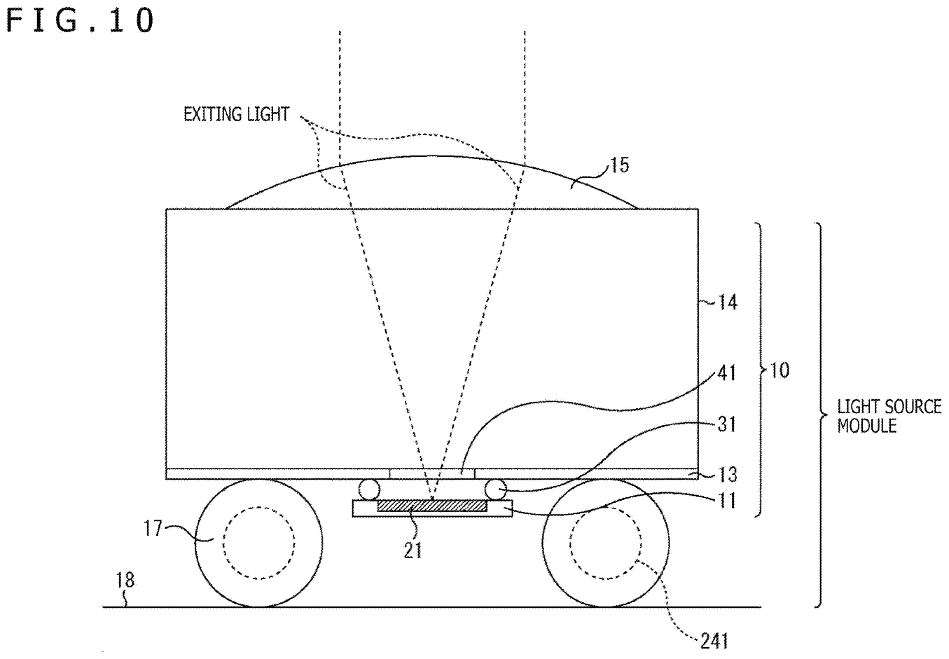

FIG. 10 is a cross-sectional view for explaining a second alternative method for mounting the light source chip 10 on the flexible board 18.

FIG. 10 is a cross-sectional view depicting the light source chip 10 mounted on the flexible board 18 by the second alternative mounting method.

In FIG. 10, for example, Cu core solder balls having therein core bodies (core members) 241 such as copper are adopted as the solder (balls) as the second bumps 17.

In a case that the second bumps 17 has therein the core bodies 241, the core bodies 241 can maintain a predetermined distance between the light source chip 10 and the flexible board 18 and reduce the likelihood of inclination of the light source chip 10 mounted on the flexible board 18.

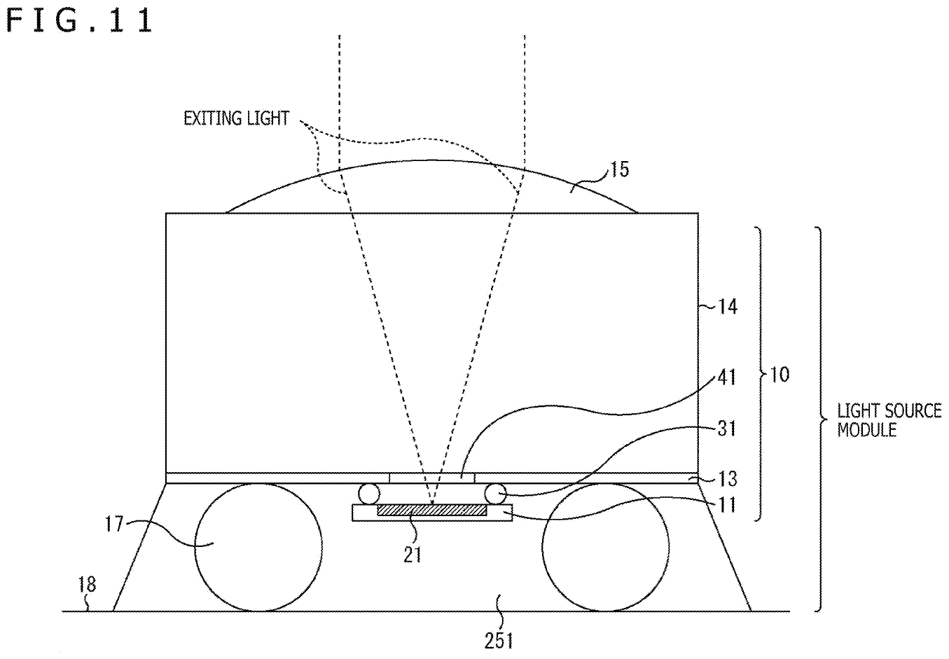

FIG. 11 is a cross-sectional view for explaining a third alternative method for mounting the light source chip 10 on the flexible board 18.

FIG. 11 is a cross-sectional view depicting the light source chip 10 mounted on the flexible board 18 by the third alternative mounting method.

Because the light-emitting board 11 is connected to the circuit board 13 by the first bumps 31 in the light source chip 10, the light-emitting board 11 seemingly stays floating in a space.

By sealing a gap between the circuit board 13 and the flexible board 18 by using an under-filler material 251 such as a sealing resin for heat dissipation in the light source chip 10 having the light-emitting board 11 in such a state, the light source chip 10 can be formed integrally with the flexible board 18. Thereby, the heat dissipation property of the structure of a light source module having the light source chip 10 mounted on the flexible board 18 can be enhanced.

Two or more mounting methods in the first to third alternative mounting methods can be combined with each other. For example, by combining the first and third alternative mounting methods with each other, the heat dissipation property can be enhanced further.

### Configuration Examples of Light Source Module

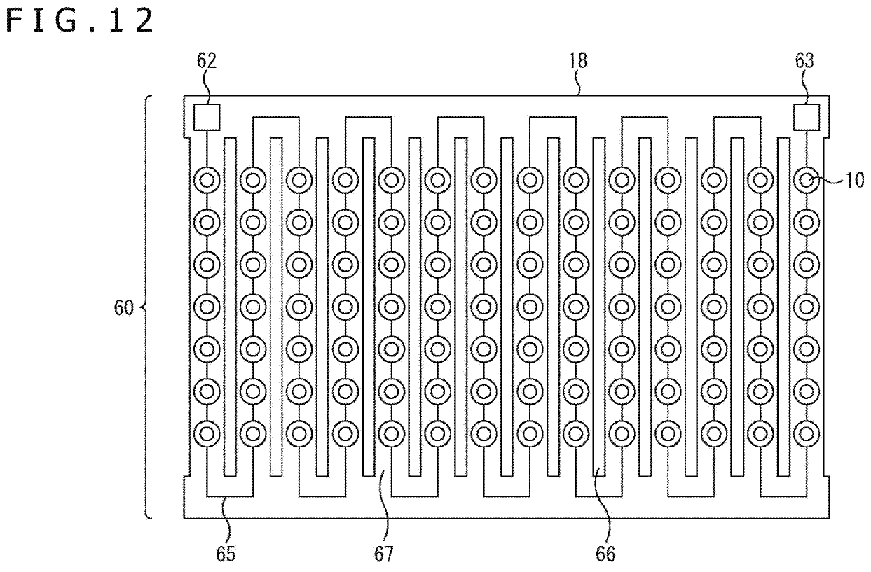

FIG. 12 is a plan view depicting a first configuration example of a light source module to which the light source chips 10 are applied.

In FIG. 12, a light source module 60 has a plurality of the light source chips 10, the flexible board 18, a control element 62, and an interface element 63.

The plurality of light source chips 10 is configured similarly to the light source chip 10 in FIG. 1 and the like and are next to each other in series on the flexible board 18 with the control element 62 being connected at their starting point, and the interface element 63 being connected at their end point.

In FIG. 12, on an approximately rectangular flexible board, the flexible board 18 is formed in a ladder shape having slits 66 as breaks provided at predetermined intervals. That is, in FIG. 12, the slits 66 are provided to leave unoccupied the top and bottom ends of the flexible board 18 in the vertical direction in the figure, and this gives the flexible board 18 a horizontally-placed ladder shape.

One or more light source chips 10 are arranged in each thin approximately rectangular strip area 67 between adjacent slits 66 of the flexible board 18. The strip areas 67 are areas corresponding to rungs of the ladder.

In FIG. 12, the control element 62 and the interface element 63 are arranged at the upper left and upper right of the flexible board 18, respectively.

The plurality of light source chips 10, the control element 62, and the interface element 63 arranged on the flexible board 18 are connected with connection wires 65. As the connection wires 65, there are, for example, a clock pair differential wire, a data pair differential wire, other several types of control wire, or the like. Furthermore, as the connection wires 65, there are, for example, an electric power supply line of a 3.3-V power supply and a GND line as connection wires of a power supply system.

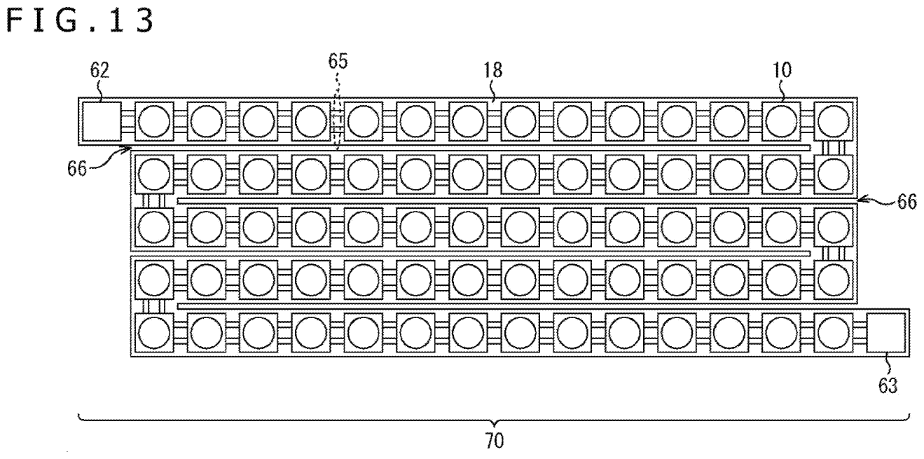

FIG. 13 is a plan view depicting a second configuration example of a light source module to which the light source chips 10 are applied.

Note that portions in the figure that have counterparts in FIG. 12 are given identical reference characters, and explanations thereof are omitted as appropriate below.

In FIG. 13, a light source module 70 has a plurality of the light source chips 10, the flexible board 18, the control element 62, and the interface element 63.

The plurality of light source chips 10 is configured similarly to the light source chip 10 in FIG. 1 and the like and are next to each other in series on the flexible board 18 with the control element 62 being connected at their starting point, and the interface element 63 being connected at their end point.

In FIG. 13, on an approximately rectangular flexible board, the flexible board 18 is formed in a zigzag shape having the slits 66 as breaks provided at predetermined intervals. That is, in FIG. 13, the slits 66 are provided to leave unoccupied the left end and right end of the flexible board 18 alternately in the horizontal direction in the figure, and this gives the flexible board 18 a zigzag shape.

The plurality of light source chips 10, the control element 62 and the interface element 63 are arranged on the zigzag-shaped flexible board 18 as mentioned above.

That is, the control element 62 and the interface element 63 are arranged at the upper left and lower right of the flexible board 18, respectively. Then, the plurality of light source chips 10 is arranged along the zigzag-shaped flexible board 18 between the control element 62 and the interface element 63 such that the control element 62 and the interface element 63 are linked like one-stroke writing.

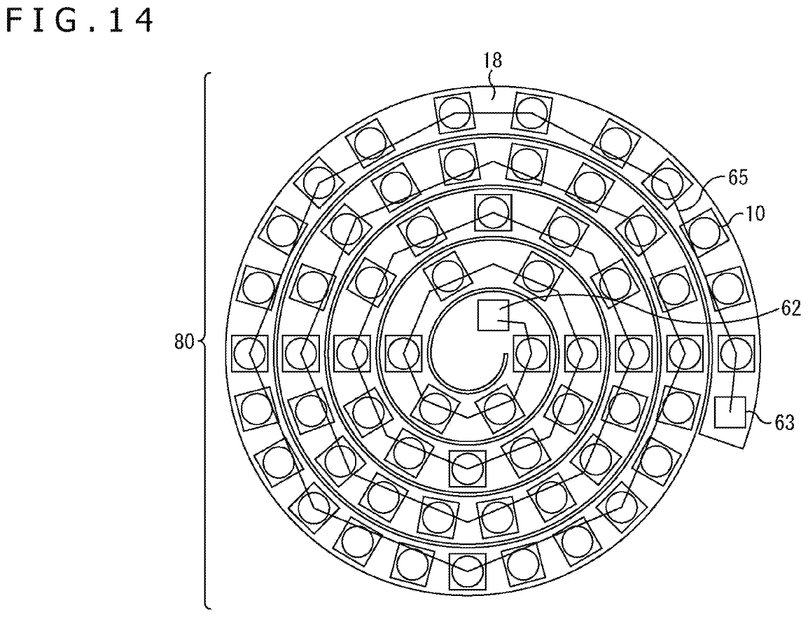

FIG. 14 is a plan view depicting a third configuration example of a light source module to which the light source chips 10 are applied.

Note that portions in the figure that have counterparts in FIG. 12 are given identical reference characters, and explanations thereof are omitted as appropriate below.

In FIG. 14, a light source module 80 has a plurality of the light source chips 10, the flexible board 18, the control element 62, and the interface element 63.

The plurality of light source chips 10 is configured similarly to the light source chip 10 in FIG. 1 and the like and are next to each other in series on the flexible board 18 with the control element 62 being connected at their starting point, and the interface element 63 being connected at their end point.

In FIG. 14, the flexible board 18 is formed in a swirl shape, and the plurality of light source chips 10, the control element 62, and the interface element 63 are arranged on such a swirl-shaped flexible board 18.

That is, the control element 62 and the interface element 63 are arranged at the inner end point and outer end point of the swirl-shaped flexible board 18, respectively. Then, the plurality of light source chips 10 is arranged along the swirl-shaped flexible board 18 between the control element 62 and the interface element 63 such that the control element 62 and the interface element 63 are linked like one-stroke writing.

The ladder-shaped, zigzag-shaped, or swirl-shaped flexible board 18 as mentioned above can be easily caused to conform to curved surfaces and various other shapes. Accordingly, the light source chips 10 arranged on the flexible board 18 can be arranged to conform to various shapes of base members which serve as the bases of light source modules.

Here, in a case that a plurality of the light source chips 10 is connected in series, the flexible board 18 may have a thin straight linear shape (a strip shape which is vertically long). However, in terms of cost reduction of the flexible board 18 to be included in a light source module, it is desirable to take out as many flexible boards 18 to serve as product boards as possible from a rectangular mother board. In view of this, preferred shapes of the flexible board 18 to be included in a light source module include a ladder shape, a zigzag shape, a swirl shape, and the like as mentioned above. It should be noted that the shape of the flexible board 18 is not limited to these shapes, but may be shapes such as other linear shapes or radial shapes.

Note that, in terms of power supply, the swirl-shaped flexible board 18, which is a very long strip with a small width, can create a concern over voltage reduction (voltage drop) or the like on a power supply layer. That is, whereas a sufficient voltage can be applied to both end sections of the swirl-shaped flexible board 18, a middle section (a portion far from the end points of the swirl) is naturally distant from a power supply section, and therefore voltage reduction due to the board wire resistance becomes a problem in some cases. On the other hand, the ladder-shaped flexible board 18 can supply power to the light source chips 10 arranged in the strip areas 67 from end sections of the strip areas 67 in the longitudinal direction. Accordingly, the ladder-shaped flexible board 18 can mitigate the problem of voltage reduction that can occur in the swirl-shaped flexible board 18. The zigzag-shaped flexible board 18 can also mitigate the problem of the voltage reduction similarly.

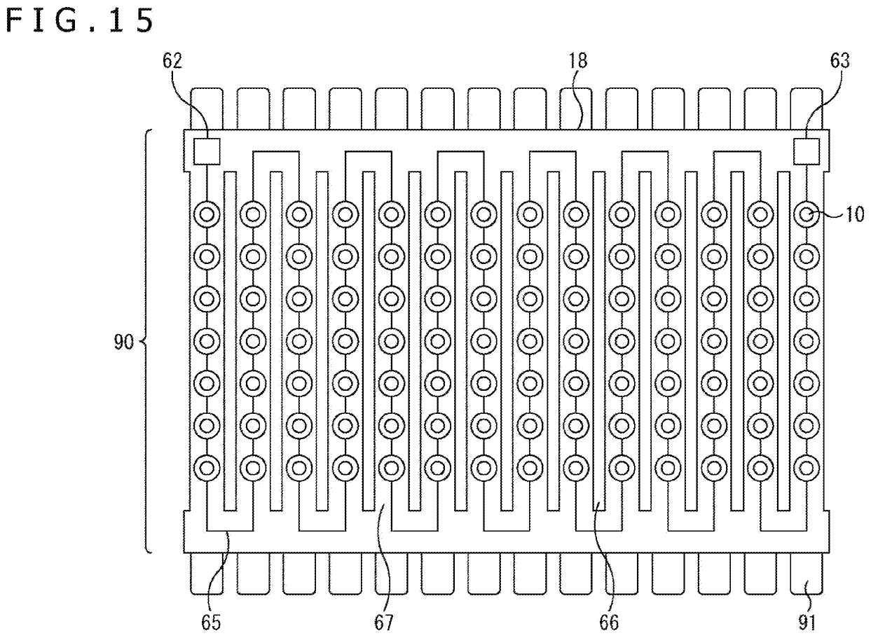

FIG. 15 is a plan view depicting a fourth configuration example of a light source module to which the light source chips 10 are applied.

Note that portions in the figure that have counterparts in FIG. 12 are given identical reference characters, and explanations thereof are omitted as appropriate below.

In FIG. 15, similarly to the light source module 60 in FIG. 12, a light source module 90 includes a plurality of the light source chips 10, the control element 62 and the interface element 63 that are arranged on the ladder-shaped flexible board 18.

Further, the light source module 90 is provided with reinforcing materials 91 that support the flexible board 18.

In FIG. 15, the reinforcing materials 91 are flat-plate members with a (widthwise) width which is approximately the same with the thickness of the strip areas 67 and a thickness of approximately 0.5 mm, and are adhered to the backsides of the strip areas 67 (surfaces opposite to surfaces on which the light source chips 10 are arranged).

The reinforcing materials 91 can include, for example, a metal such as stainless, aluminum, or copper.

In a case that the reinforcing materials 91 include aluminum or copper, the heat dissipation property can be enhanced. It is preferred to use an adhesive having a high heat dissipation property as an adhesive used for adhering the reinforcing materials 91 to (the strip areas 67 of) the flexible board 18.

The flexible board 18 having the reinforcing materials 91 adhered thereon as mentioned above deforms along with the reinforcing materials 91 and thus maintains the shape after the deformation.

Accordingly, the flexible board 18 can be deformed into a desired shape, and the arrangement of the light source chips 10 conforming to the desired shape can be realized, without damaging the light source chips 10 arranged on the flexible board 18.

For example, by deforming, in advance, the flexible board 18 having the reinforcing materials 91 adhered thereon into a desired shape by using a jig or the like, and adhering and fixing, by using an adhesive or the like, the flexible board 18 after the deformation onto a base member including a metal such as aluminum or aluminum nitride, the light source chips 10 can be arranged to conform to a surface of the base member.

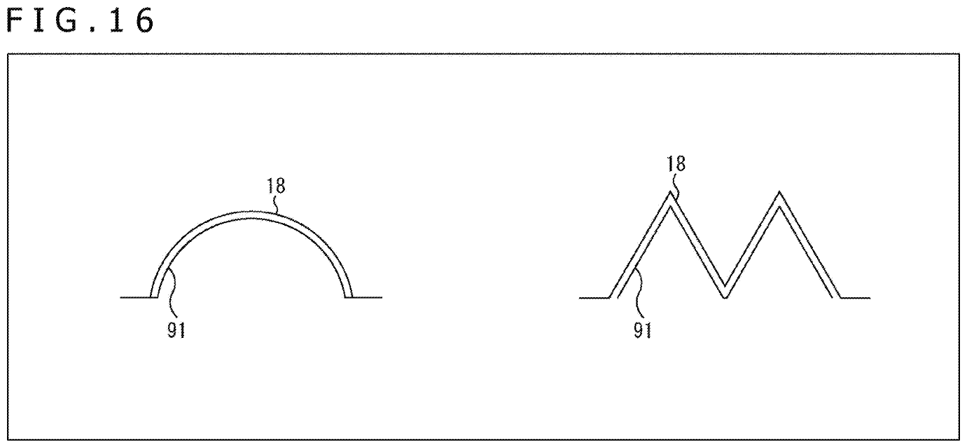

FIG. 16 is a cross-sectional view depicting examples of deformation of the flexible board 18 having a reinforcing material 91 adhered thereon.

By pressing the flexible board 18 having the reinforcing material 91 adhered thereon against, for example, a base member having a hemispherical surface or a base member having a surface with a triangular recessed and protruding shape, the flexible board 18 can be easily deformed into the shape of the surface of the base member. That is, the flexible board 18 can be easily deformed into, for example, the hemispherical (curved) shape, the triangular recessed and protruding shape, another complicated three-dimensional shape, or the like.

Note that, other than being provided on the ladder-shaped flexible board 18, the reinforcing materials 91 can be provided on the zigzag-shaped flexible board 18, the swirl-shaped flexible board 18, and the like.

### Configuration Examples of Distance Measurement Module

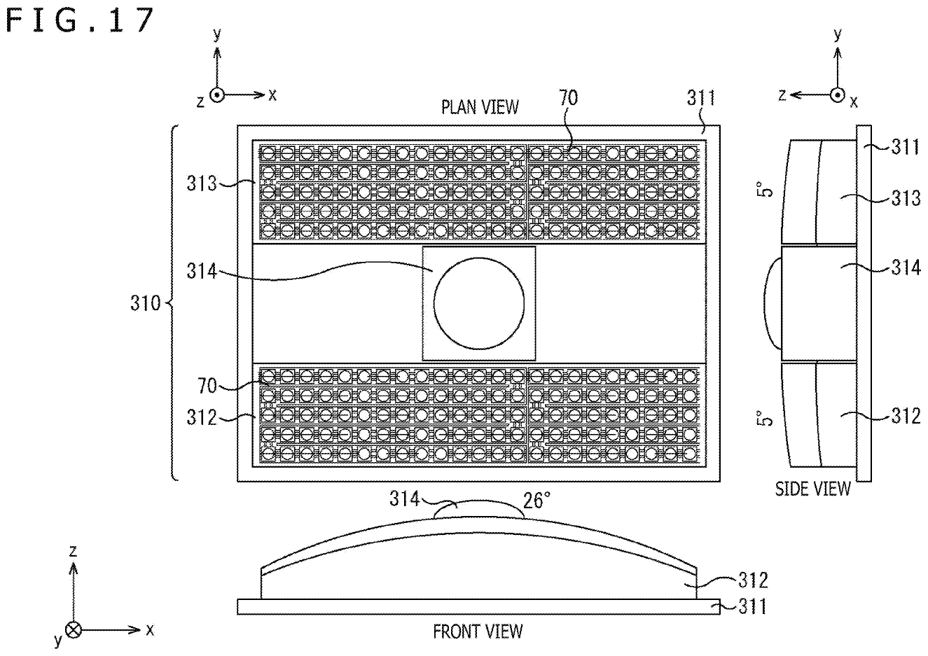

FIG. 17 is a figure depicting a first configuration example of a distance measurement module to which the light source chips 10 are applied.

In FIG. 17, a distance measurement module 310 includes the light source module 70, a substrate 311, base members 312 and 313, and a light-receiving section 314.

The substrate 311 includes a flat-plate board. In the front view, the base members 312 and 313 are arranged on the nearer side and farther side of the substrate 311, respectively, and the light-receiving section 314 is arranged between the base members 312 and 313.

The base member 312 includes a material having a high heat dissipation property, for example, a metal such as aluminum or ceramics such as aluminum nitride. The base member 312 is configured in a rectangular parallelepiped shape which is horizontally long when seen in the front view. The top surface of the base member 312 is curved in the x-y direction, and has a curved surface.

Then, the light source module 70 (FIG. 13) is attached to the top surface of the base member 312 by adhesion or the like. By providing the reinforcing materials 91 to the light source module 70, and pressing and deforming, along with the reinforcing materials 91, the flexible board 18 against the top surface of the base member 312 in advance, (the flexible board 18 of) the light source module 70 can be easily adhered to conform to the curved surface of the top surface of the base member 312.

The curved surface of the top surface of the base member 312 is curved such that perpendicular lines perpendicular to the curved surface spread within the range of 26 degrees in the front view and spread within the range of 5 degrees in the side view. Accordingly, light exits from the light source module 70 attached to such a curved surface such that the light spreads radially.

The base member 313 is configured such that the base member 313 becomes axially symmetrical to the base member 312 in a state that both are arranged on the substrate 311.

As mentioned above, the base members 312 and 313 and the light-receiving section 314 are arranged on the substrate 311, and the light source module 70 is attached to the base members 312 and 313. Accordingly, the light source chips 10 of the light source module 70 and the light-receiving section 314 can be said to be arranged on the substrate 311 as one board.

As mentioned above, the light-receiving section 314 is arranged between the base members 312 and 313. Accordingly, the light source chips 10 of the light source module 70 adhered to the base members 312 and 313 are arranged around the light-receiving section 314.

The light-receiving section 314 has, for example, a light-receiving element (not depicted) such as an SPAD that receives light, and receives reflection light which is light having exited from the light source chips 10, and returning after being reflected off of a distance measurement target object. Then, the light-receiving section 314 (or a circuit which is not depicted) calculates the distance to the target object on the basis of the length of time that elapses from the time at which the light has been caused to exit from the light source chips 10 until the time at which the reflection light of the light is received.

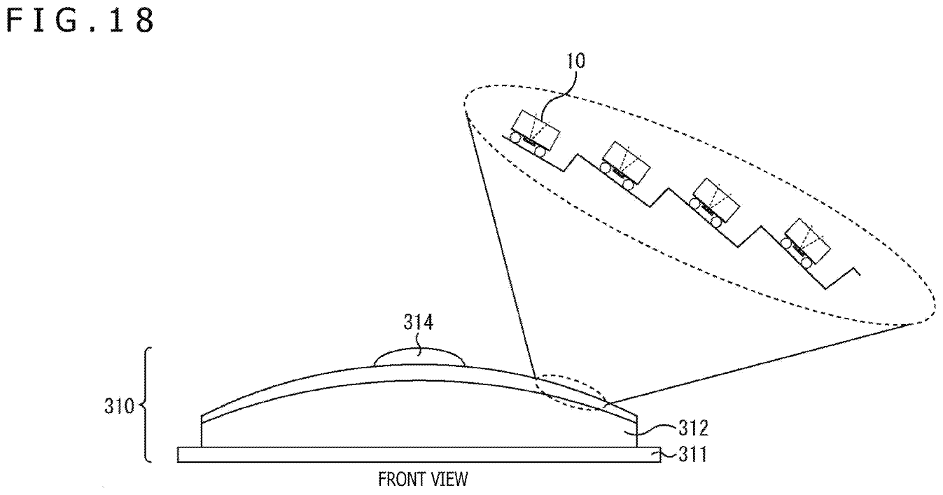

FIG. 18 is a front view for explaining a configuration example of the base member 312.

Note that the base member 313 is configured similarly to the base member 312.

The top surface of the base member 312 is a curved surface as explained with reference to FIG. 17. Other than being formed as a smooth curved surface, the curved surface of the top surface of the base member 312 can be configured as a curved surface having steps formed thereon as depicted in FIG. 18, and (the flexible board 18 of) the light source module 70 can be attached onto such a curved surface having the steps formed thereon.

In a case that the curved surface of the top surface of the base member 312 is configured such that perpendicular lines spread within a predetermined angular range as explained with reference to FIG. 17, the height of the base member 312 can be lowered more by adopting, as the curved surface, a curved surface having steps formed thereon than a smooth curved surface. Accordingly, it is possible to attempt to achieve size reduction of the distance measurement module 310.

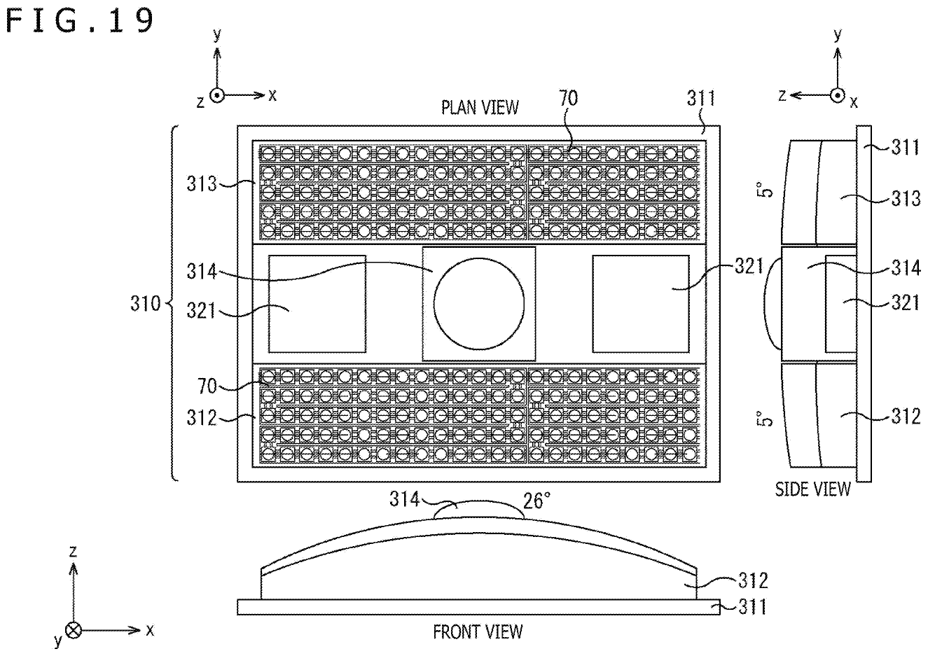

FIG. 19 is a figure depicting a second configuration example of the distance measurement module to which the light source chips 10 are applied.

Note that portions in the figure that have counterparts in the case of FIG. 17 are given identical reference characters, and explanations thereof are omitted as appropriate below.

In FIG. 19, the distance measurement module 310 includes the light source module 70, the substrate 311, the base members 312 and 313, the light-receiving section 314, and fans 321.

Accordingly, the distance measurement module 310 in FIG. 18 is the same as in the case of FIG. 17 in that the distance measurement module 310 has the light source module 70, the substrate 311, the base members 312 and 313, and the light-receiving section 314. It should be noted that the distance measurement module 310 in FIG. 18 is different from the distance measurement module 310 in the case of FIG. 17 in that the fans 321 are provided additionally.

The fans 321 are an example of a cooling mechanism that cools the base members 312 and 313, and one fan 321 is provided to each of the left and right of the light-receiving section 314 in the plan view in FIG. 19.

Note that, other than the fans 321, heat sinks can be adopted as the cooling mechanism that cools the base members 312 and 313. In addition, for example, the base members 312 and 313 can be shaped in grids, and the grid-like base members 312 and 313 can be adopted as the cooling mechanism. Furthermore, a plurality of the cooling mechanisms mentioned above can be adopted.

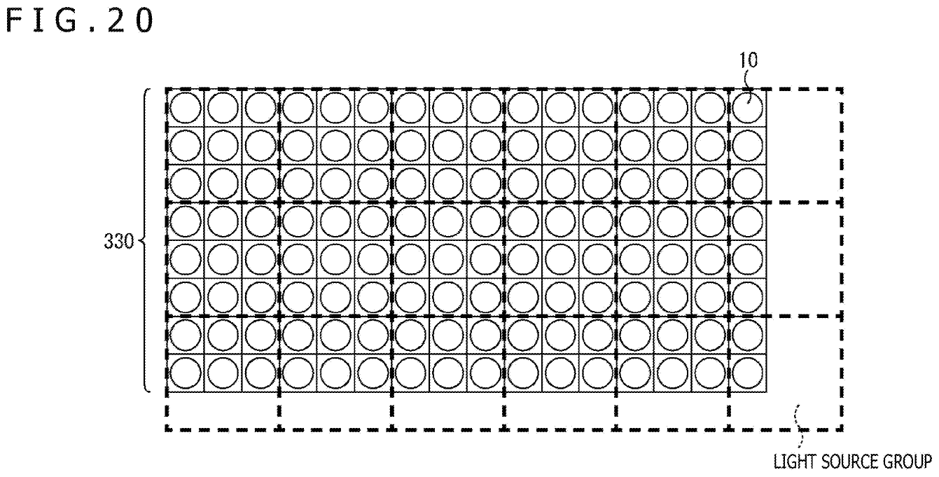

FIG. 20 is a figure for explaining control of a light source module 330 including a plurality of the light source chips 10 arranged therein.

For example, in the light source module 330 including the plurality of light source chips 10 arranged therein like the light source modules 60, 70, 80 and 90 and the like, for example, the light source chips 10 can be grouped into groups each with a size of 3×3 light source chips 10 in the widthwise direction and depthwise direction, and thus can be grouped into light source groups each including 3×3 light source chips 10 or fewer. Then, light emission limit control of limiting light emission of the light source chips 10 can be performed such that, for example, only one light source chip 10 in each light source group is caused to emit light simultaneously. In the light emission limit control, the one light source chip 10 to be caused to emit light in each light source group can be selected sequentially or randomly.

By performing the light emission limit control, in the light source module 330, for example, light source chips 10 that are spaced two light source chips 10 apart in the widthwise direction and the depthwise direction are caused to emit light simultaneously.

According to the light emission limit control as mentioned above, in the light source module 330, simultaneous emission of light source chips 10 that are adjacent (in the widthwise direction, the depthwise direction, and the diagonal directions) is limited, and thus it is possible to comply with laser safety standards.

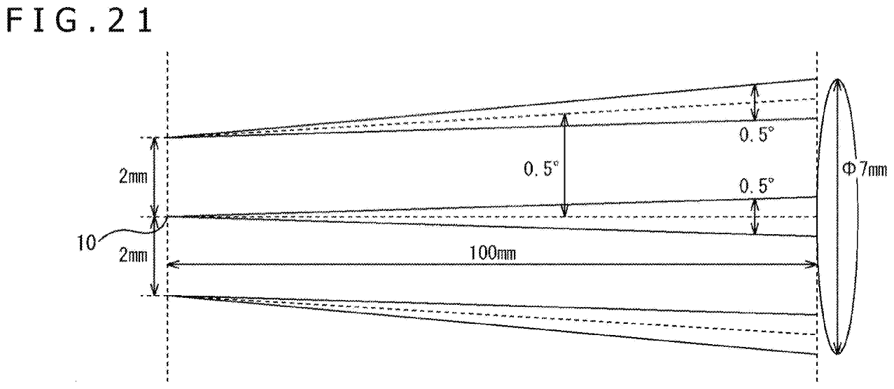

FIG. 21 is a figure for explaining laser safety standards.

In a case that, in the light source module 330 having the plurality of light source chips 10 arranged therein, the light source chips 10 cause light (beams) corresponding to Class 1M of the laser safety standards to exit therefrom (emit the light), simultaneous emission of light from all of the light source chips 10 arranged in the light source module 330 can cause non-conformance to the laser safety standards.

For example, the laser safety standards stipulate that, in a case that light (beams) with a wavelength of 905 nm is used as exiting light (emitted light), the pulse interval should be equal to or longer than 5e-6, and AEL should be equal to or lower than 1.98e-7J (measurement area: area of φ7 mm at a distance of 100 mm).

It is supposed here that the plurality of light source chips 10 is arranged in the light source module 330 at a pitch of 2 mm in the widthwise direction and the depthwise direction and at an inclination angle of 0.5 degrees and light exits therefrom at a beam divergence angle of 0.5 degrees.

In this case, if adjacent light source chips 10 in the light source module 330 emit light simultaneously, the area of φ7 mm at a distance of 100 mm defined by the laser safety standards is irradiated with light having exited from a plurality of the light source chips 10. As a result, the light intensity in the area does not conform to the laser safety standards.

In view of this, by performing the light emission limit control in the light source module 330 to limit the number of light source chips to emit light simultaneously to one per light source group, it is possible to comply with the laser safety standards.

Furthermore, the light intensity of light that exits from each light source chip 10 in the light source module 330 can be set to the highest value that complies with the laser safety standards.

### Alternative Configuration Examples of Light Source Modules

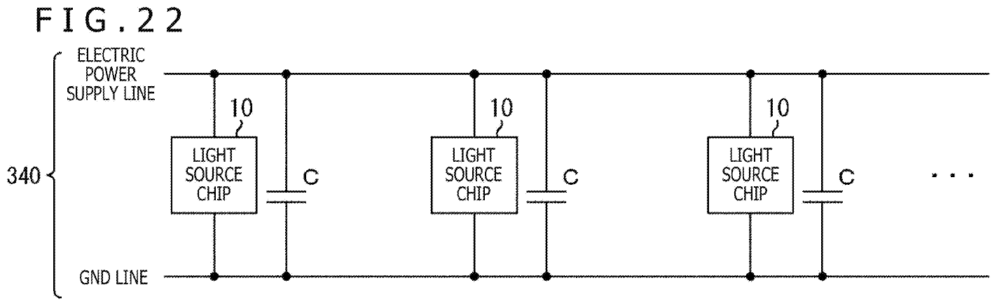

FIG. 22 is a block diagram depicting a fifth configuration example of a light source module to which the light source chips 10 are applied.

In FIG. 22, a light source module 340 includes a plurality of the light source chips 10 arranged therein. Furthermore, in the light source module 340, each of the light source chips 10 is provided with, for example, a 10- to 100-uF capacitor C which is located near the light source chip 10 and connects an electric power supply line and a GND line.

For example, in a case that the light intensity of light to exit from each light source chip 10 is set to the highest value that complies with the laser safety standards on the premise that the light emission limit control is performed in the light source module 340 as explained with reference to FIG. 21, each light source chip 10 emits light at light intensity (corresponding to electric power) which is as high as 15 W at a pulse width of 5 ns, for example.

In this case, it becomes difficult in some cases for all of the light source chips 10 of the light source module 340 to obtain sufficient electric power from the electric power supply line and the GND line.

For example, in a case that the light source module 340 is the light source module 60 in FIG. 12 having the ladder-shaped flexible board 18, and electric power is supplied from the top and bottom ends, in FIG. 12, of the ladder-shaped flexible board 18 toward the inner side, paths to supply electric power to light source chips 10 that are far from the top and bottom ends of the flexible board 18 are longer than paths to supply electric power to light source chips 10 that are close to the top and bottom ends.

In this case, when light source chips 10 that are far from the top and bottom ends of the flexible board 18, and light source chips 10 that are close to the top and bottom ends emit light simultaneously, sufficient electric power is not supplied to the light source chips 10 that are far from the top and bottom ends of the flexible board 18 instantaneously in some cases.

In view of this, by arranging the capacitors C near the light source chips 10 and causing the capacitors C to perform what is called assistance of electric power supply to the nearby light source chips 10, the likelihood that the light source chips 10 are not supplied with sufficient electric power instantaneously can be reduced.

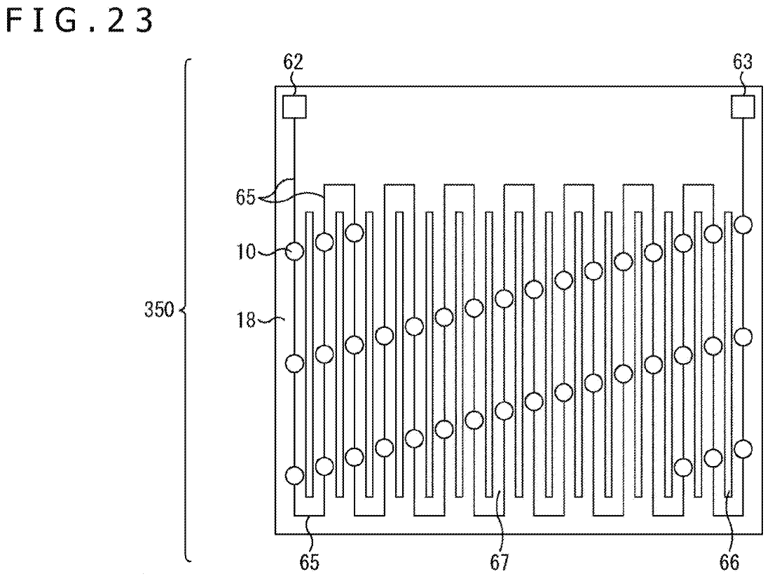

FIG. 23 is a plan view depicting a sixth configuration example of a light source module to which the light source chips 10 are applied.

Note that portions in the figure that have counterparts in the light source module 60 in FIG. 12 are given identical reference characters, and explanations thereof are omitted as appropriate below.

In FIG. 23, a light source module 350 has a plurality of the light source chips 10, the flexible board 18, the control element 62, and the interface element 63.

The plurality of light source chips 10 is configured similarly to FIG. 1 and the like, and are connected in series in one line with the control element 62 (Control-IC) being connected at their starting point, and the interface element 63 (TransferJet-IC) being connected at their end point.

In the light source module 350, two or three light source chips 10 are arranged next to each other in the depthwise direction in one strip area 67. Furthermore, in the light source module 350, the light source chips 10 are arranged on the flexible board 18 such that the positions, in the depthwise direction, of the light source chips 10 relative to the flexible board 18 are shifted by a predetermined amount.

The control element 62 at the starting point receives data from a superordinate system, and, in accordance with the data, sends out trigger signals or light-emission-pattern data at constant intervals. For example, in a case that the operation time from light emission of the light source chips 10 to writing of history data is shorter than 0.5 ms, the control element 62 sends out trigger signals or light-emission-pattern data at intervals which are equal to or longer than 0.5 ms. The following light source chips 10 receive the trigger signals or light-emission-pattern data from the control element 62, sequentially start light emitting operation by what is called bucket brigade, and transmit packet data of various types of history obtained by the light emitting operation.

The interface element 63 at the end point receives the packet data from the light source chips 10 and transmits the packet data to the superordinate system. More specifically, the interface element 63 transmits, to a CPU of the superordinate system, the packet data as serial data received from the light source chips 10. There are no problems even if the transmission is performed wiredly or wirelessly, but wireless transfer is desirable. Standards of wireless transfer include, for example, TransferJet (registered trademark) and the like.

Note that the interface element 63 can have a functionality of receiving, from the light source chips 10, light emission timing history information (history data), error information and the like, and giving feedback about the operation situation to a superordinate system that separately performs overall control. It should be noted that this functionality can be omitted. The light source module 350 can cause the light source chips 10 to emit light in accordance completely open control.

Whereas the one flexible board 18 is provided with the connection wire 65 as one serial wire group in FIG. 23, a plurality of serial wire groups may be provided in parallel as the connection wire 65. In a case that a plurality of serial wire groups is provided as the connection wire 65, a plurality of control elements 62 to be connected with the plurality of serial wire groups, respectively, can be provided, and further a superordinate control element (a superordinate control IC) that distributes data to the plurality of control elements 62 can be provided.

Here, in a case that the light emission pattern in the light source module 350 is complicated or in a case that the number of the light source chips 10 is large in the order of several hundreds or several thousands, an enormous amount of data is transmitted from the superordinate system to the control element 62. In this case, communication between the superordinate system and the control element 62 may be performed not wirelessly but wiredly.

It should be noted that, in a case that communication between the superordinate system and the control element 62 is performed wiredly, when the light source module 350 is attached to and rotates relative to a base member, a rotary contact or the like that is not constrained by rotation is necessary in order to electrically connect the superordinate system and the control element 62.

If a rotary contact is used, noise is superimposed on data that goes through the rotary contact, and accurate data cannot be transmitted in some cases. In view of this, communication between the superordinate system and the control element 62 can be performed by contactless optical transfer. The optical transfer can be performed by providing an optical transfer path for sending pulsed light at a coaxial section between a rotation shaft and a fixed shaft for rotating the light source module 350 attached to the base member, and the like.

In addition, whereas data transmission can be performed by bucket brigade in the plurality of light source chips 10 connected in series, the manner of transmission is not limited to bucket brigade. Data transmission can be performed, for example, in an analog manner in the plurality of light source chips 10 connected in series. In addition, the configuration of data transmitted by the light source chips 10, and the form of connection between the plurality of light source chips 10 are not limited particularly.

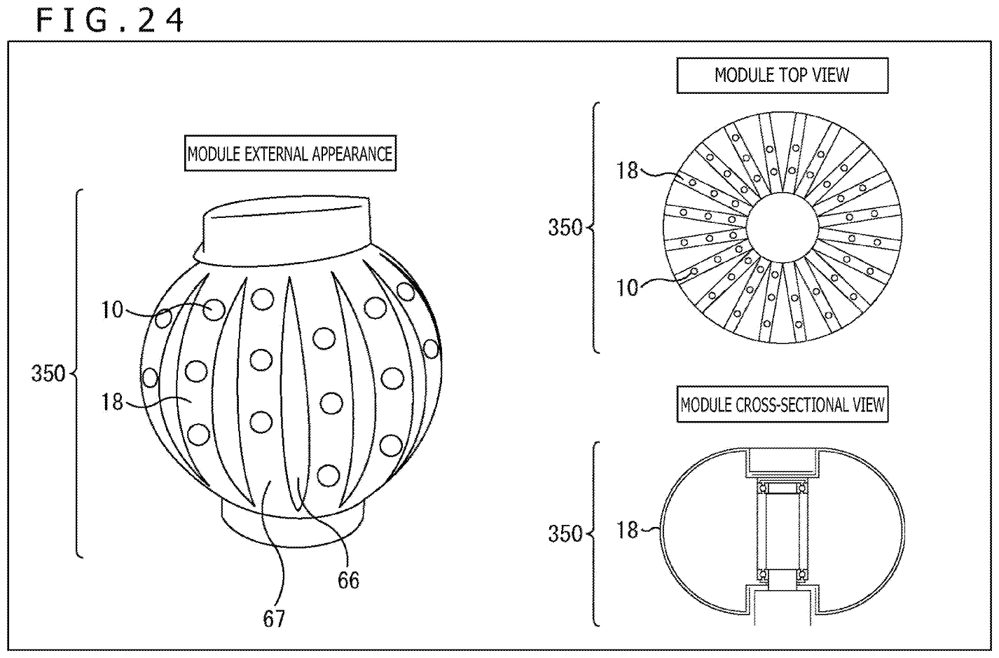

FIG. 24 is a figure depicting an assembly example of the light source module 350 in FIG. 23.

In FIG. 24, the light source module 350 is assembled into a lantern-type light source module.

In FIG. 24, the flexible board 18 is deformed such that the strip areas 67 having the plurality of light source chips 10 arranged therein as depicted in FIG. 23 form lines of longitude (meridians) of a ball (the earth), and thus the light source module 350 is configured in a shape like a slightly vertically-collapsed spherical lantern.

That is, in FIG. 24, by attaching the flexible board 18 of the light source module 350 onto a slightly vertically-collapsed spherical (approximately spherical) base member as if the flexible board 18 is wound around the base member, the approximately spherical light source module 350 whose strip areas 67 of the flexible board 18 form lines of longitude is configured.

The light source chips 10 are arranged on the flexible board 18 such that light emitted by the light-emitting boards 11 exit outward (in directions of perpendicular lines of the spherical surface). Note that, in FIG. 24, the control element 62, the interface element 63, and the connection wire 65 are not depicted to avoid complicated figures.

In the assembling process of assembling the light source module 350 into a lantern-type light source module, the flexible board 18 of the light source module 350 is pasted onto and fixed to a base member having a curved surface with a protruding shape, a spherical shape, or the like.

The positioning to be performed in a case that the flexible board 18 is pasted onto and fixed to the base member can be performed, for example, as fitting positioning in which holes are formed through the flexible board 18 and protrusions or the like are provided on the base member to fit the protrusions of the base member into the holes of the flexible board 18.

Other than this, the positioning may be positioning fixation in which holes are provided through both the flexible board 18 and the base member and pins for positioning are used. Thus, (the exiting directions of light of) the light source chips 10 can be aligned with directions vertical to the curved surface, and projection in directions relevant to the respective light source chips 10 becomes possible.

Major specifications of the light source module 350 such as light emission angles or resolution can be set freely by changing the mounting positions, pitch, or the like of the light source chips 10. The specifications can also be set such that light is caused to exit at high resolution in certain directions and light is caused to exit at low resolution in the other directions.

It should be noted that, because the number of light source chips 10 necessary for the light source module 350 is proportional to the resolution, for example, if it is attempted to give the light source module 350 high resolution equal to or lower than one degree, a large number of light source chips 10 are necessary.

For example, in a case that projection is performed omnidirectionally at resolution in the depthwise and widthwise directions of 0.1 degrees (in a case that light is to be caused to exit omnidirectionally), approximately 6.5 million (≈360/0.1×180/0.1) light source chips 10 are necessary.

In a case that such high resolution is necessary, a structure that rotates a base member is effective for cost reduction.

In this case, the light source chips 10 can be mounted, for example, at intervals of 10 degrees (360/10 points) in the H (Horizontal) direction (in the direction along the lines of latitude) and at intervals of 3.6 degrees (180/3.6 points) in the V (Vertical) direction (in the direction along the lines of longitude). Further, in the mounting of the light source chips 10, the mounting positions are offset at intervals of 0.1 degrees.

By attaching, to the base member, the light source module 350 having the light source chips 10 mounted thereon in the manner mentioned above, assembling the light source module 350 into a lantern-type light source module, and causing the light source module 350 to perform rotational scanning, the resolution of 0.1 degrees can be realized by a mere 1800 (=360/10×180/3.6) light source chips 10.

In a case that light emission control of causing light source chips 10 to emit light and not to emit light 3600 times (=360 degrees/0.1 degrees) per rotation, and it takes 5 μs to perform the light emission control once, light can be projected omnidirectionally at resolution of 0.1 degrees by performing one rotation in 0.018 s (=5 μs×3600 times).

For example, by causing the light source chips 10 included in the light source module 350 to emit R (Red), G (Green), and B (Blue) visible light as appropriate, an omnidirectional spherical projector that projects color images omnidirectionally can be realized.

In addition, for example, by causing the light source chips 10 included in the light source module 350 to emit infrared light with multiple types of wavelength such as three types of wavelength as appropriate, a rewritable full color paper can be realized by using a paper-like device that displays different colors in accordance with the wavelength of infrared light with which the device is irradiated.

Note that, for example, the light intensities can be changed in the light emission control of the light source chips 10. In addition, for example, PWM control can be performed in the light emission control of the light source chips 10.

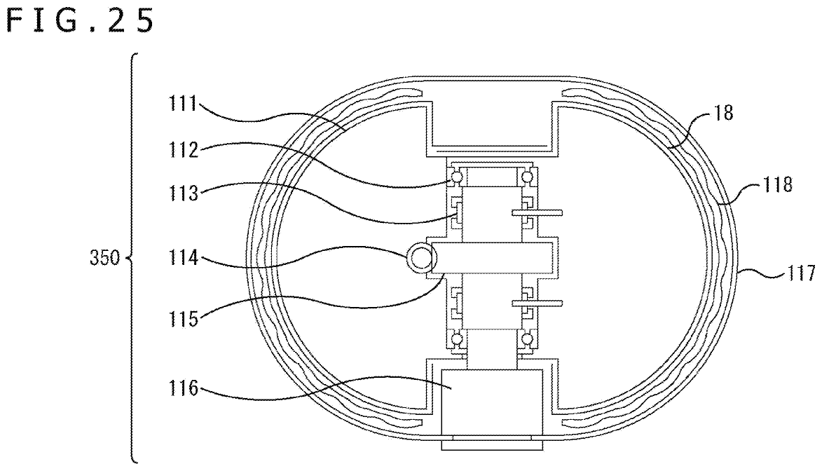

FIG. 25 is a cross-sectional view depicting a configuration example of the light source module 350 assembled into a lantern-type light source module.

In FIG. 25, the light source module 350 includes a flexible base (base member) 111, a main bearing 112, a rotary contact 113, a micro DC motor 114, a main gear 115, a main shaft 116, a transparent cover 117, a lens array 118, and the like.

The flexible board 18 provided with light source chips 10 (not depicted in FIG. 25) is attached onto the light source module 350 such that the light source chips 10 form lines of longitude along the outer surface of the slightly vertically-collapsed spherical flexible base 111.

The micro DC motor 114 fits to the main gear 115. In accordance with driving of the micro DC motor 114, torque is transferred to the main gear 115, the main shaft 116 fits to the main gear 115, the main gear 115 and components including the flexible board 18 of the light source module 350 other than the transparent cover 117 rotate about the main shaft 116. That is, while the micro DC motor 114 is generating rotational torque, the micro DC motor 114 itself also rotates about the main shaft 116 integrally with other components. Similarly to a lens array 372 to be mentioned later, the lens array 118 is included in a dual-lens structure to be mentioned later.

Note that the drive section (means) that rotation-drives the light source module 350 is not limited to the micro DC motor 114, but may be any motor as long as the drive section is a motor such as a frameless motor that generates torque.

The rotation structure of the light source module 350 may use typical bearings. Electrical power supply may be performed by a typical electrical power supply method that uses a brush or the like or a contactless coil manner. The positional and phase detection of a rotational base member such as the flexible base 111 may be performed by using a typical hole element or the like. Data transmission in light emission control or the like to the light source module 350 may be performed by wired transfer by using electrodes or the like or by optical transfer, but may be performed by wireless transfer by TransferJet (registered trademark) or the like.

The light-emitting board 11 as a light source and the lens 15 (and/or the lens array 201, 211, or 221) as an optical part in the light source chips 10 can be integrated together at a chip level, and therefore it is not necessary to perform positioning of them. That is, according to the light source chips 10, a light source chip having the light-emitting element 21, the lens 15, and the like that are integrated together, and further a light source module to which such light source chips are applied can be provided with simple structures. Therefore, a small-sized, lightweight, and inexpensive apparatus that does not require maintenance can be realized.

Note that the light source module 350 assembled into a lantern-type light source module can perform, for example, scanning with combined patterns of motion such as reciprocal oscillating scanning or two-dimensional oscillating and rotational scanning, other than rotational scanning.

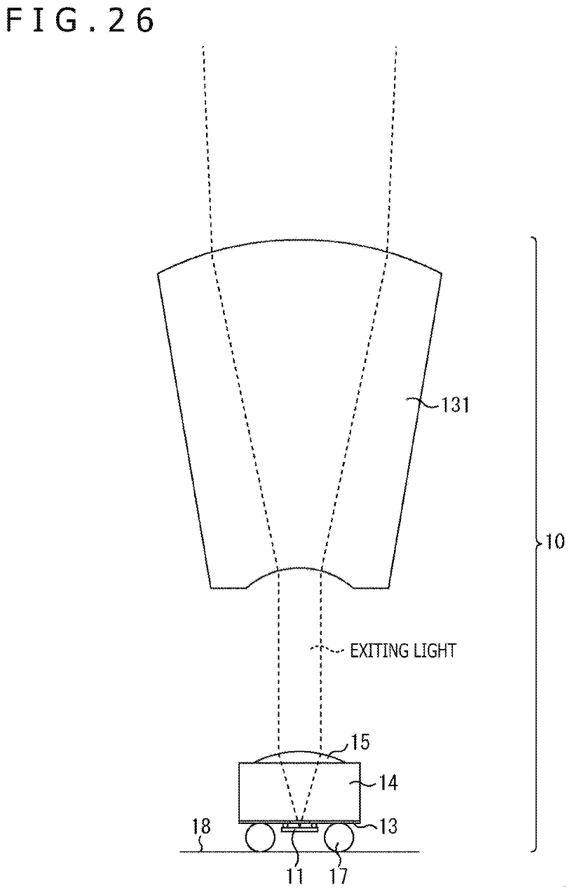

FIG. 26 is a cross-sectional view depicting a seventh configuration example of the light source chip to which the present technology is applied.

Note that portions in the figure that have counterparts in the case of FIG. 4 are given identical reference characters, and explanations thereof are omitted as appropriate below.

Here, in order for the light source chip 10 to realize longer-distance irradiation of light, it is effective to increase the distance between the light-emitting board 11 and the lens 15.

However, in a case that the lens 15 is formed at semiconductor steps, if the distance between the light-emitting board 11 and the lens 15 is increased, the size of the lens 15 and consequently the chip size of the light source chip 10 increase, and the costs of the light source chip 10 increase significantly.

In view of this, FIG. 26 depicts a configuration example of the light source chip 10 with a dual-lens structure.

By adopting a dual-lens structure in the light source chip 10, longer-distance irradiation of light can be realized while cost increases of the light source chip 10 are kept small.

In FIG. 26, an inexpensive resin molded lens 131 is arranged above the light source chip 10, and thus the light source chip 10 has a dual-lens structure having the resin molded lens 131 in addition to the lens 15. Note that the light source chip 10 can be provided with one or more lenses in addition to the lens 15 and the resin molded lens 131.

It is supposed that the diameter of the resin molded lens 131 is, for example, φ3.8 mm which is approximately twice as large as the circuit board 13. The lens 15 (one lens) and the resin molded lens 131 (another lens) are collimate-coupled by collimated light of φ1.2 mm, for example. Thus, for example, even if (optical) axial misalignment of ±0.2 mm occurs between the lens 15 and the resin molded lens 131, stable collimated light can be formed almost without deterioration of the coupling efficiency.

For example, in a case that the light source chip 10 in FIG. 26 is to be applied to the light source module 350 to be assembled into a lantern-type light source module, a transparent cover is placed on to seal outermost sections such that the lens 15 and the resin molded lens 131 are covered completely. In a case that the light source chip 10 in FIG. 26 is applied to a light source module, like the light source module 350 to be assembled into a lantern-type light source module, from which light is caused to exit omnidirectionally, a seamless transparent cover is necessary.

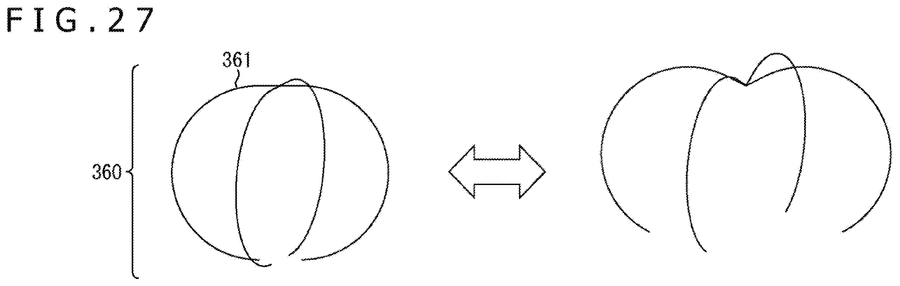

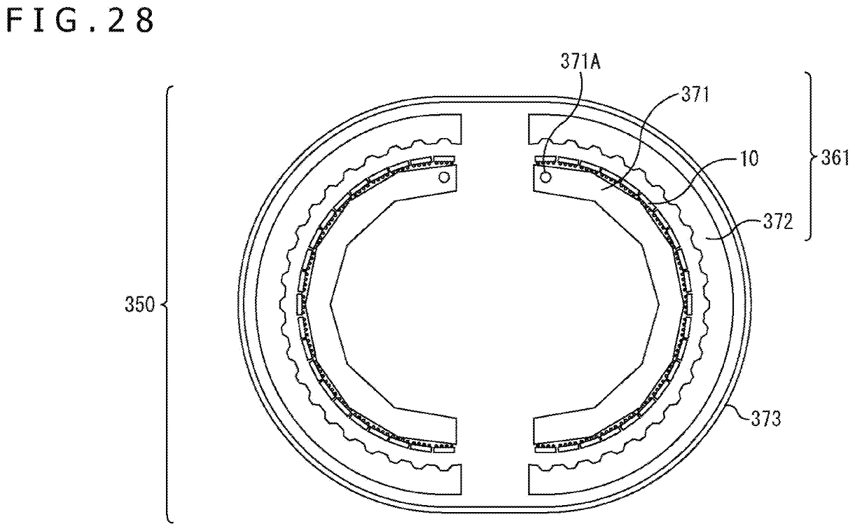

FIG. 27 is a perspective view depicting an overview of a seventh configuration example of a light source module to which the light source chips 10 are applied, and FIG. 28 is a cross-sectional view depicting the seventh configuration example of the light source module.

A light source module 360 is configured, for example, by arranging four semi-arc-like outer rib sections 361 such that the outer rib sections 361 form a spherical surface.

The four arc-like outer rib sections 361 are arranged in the light source module 360 such that the angles therebetween are 90 degrees, and can be opened and closed as depicted in FIG. 27 like outer ribs of an umbrella, with ends of the outer rib sections 361 on one side as fulcrums.

As depicted in FIG. 28, the light source module 360 can be configured by attaching the thin rectangular flexible board 18 having the light source chips 10 mounted thereon to base members 371 which have shapes like the frame of an umbrella and serve as the outer rib sections 361.

An outer rib section 361 is configured by attaching the thin rectangular flexible board 18 having the light source chips 10 mounted thereon to an arc-like base member 371, and further arranging a lens array 372 included in a dual-lens structure above the light source chips 10 (such that the lens array 372 is located in directions in which light is caused to exit). A transparent cover 373 is arranged in a state that the cover 373 is separately fixed above the lens array 372.

The outer rib sections 361 pivot (are opened and closed) with their ends 371A of the arc-like shapes on one side as fulcrums.

The light source module 360 can be configured by mounting 30 (=180/6) light source chips 10 at intervals of 6 degrees in the V direction of the respective base members 371 of the four outer rib sections 361 that form 90 degrees as mentioned above and further offsetting the mounting positions of the light source chips 10 at intervals of 1.5 degrees for each outer rib section 361.

Then, by causing the light source module 360 to perform rotational scanning and changing the angles of the outer rib sections 361 by 0.1 degrees per rotation, light can be caused to exit omnidirectionally at resolution of 0.1 degrees with 120 (=4×30) light source chips 10.

In a case that light emission control of the light source chips 10 is performed 3600 times (=360 degrees/0.1 degrees) per rotation, and it takes 5 μs to perform the light emission control once, one rotation is performed in 0.018 s (=5 μs×3600 times). In this case, light can be projected omnidirectionally at resolution of 0.1 degrees by 15 rotations (=1.5/0.1).

Note that opening and closing of the outer rib sections 361 can be realized by a typical link mechanism.

In addition, for example, in order to maintain sharp collimated light to a distant location which is at a distance of 100 m or longer or the like, for example, it is effective to keep the distance between the light-emitting board 11 and the lens 15 at, for example, 10 mm or longer in the light source chip 10 in FIG. 4. In addition, it is effective to temporarily make light that exits from the light-emitting board 11 large by increasing the lens diameter of the lens 15, and generate collimated light therefrom or slightly reduce the diameter of the light. For this purpose, it is effective to further provide one or more lenses above the lens 15 as in the dual-lens structure in FIG. 26.

In view of this, regarding the light source module 350 to be assembled into a lantern-type light source module and the light source module 360 configured by using the base members 371 having a shape like the frame of an umbrella, for example, a lens can be fabricated with a material which is transparent to exiting light of the light source chips 10, for example, an injection-molded resin or the like, for a dome-like structure, and the lens can be arranged above each of the plurality of light source chips 10. Alternatively, a dome-like lens array having a lens to be arranged above each of the plurality of light source chips 10 can be fabricated at once by injection molding, and can be arranged to entirely cover all of the light source chips 10. The lens array 372 includes such a lens array.

In a case that the dome-like lens array is arranged above the plurality of light source chips 10, it is difficult to align each of the optical axes of the lenses of the lens array and a corresponding one of the optical axes of the plurality of light source chips 10 with accuracy of, for example, ±50 μm or smaller. In view of this, in one possible optical design that can be adopted, the light source chips 10 and the lens array are collimate-coupled by collimated light, and for example even if optical axial misalignment of approximately ±100 μm has occurred, the coupling loss can be kept at or lower than 1 dB, for example.

As mentioned above, the present technology can provide the light source chips 10 that are widely applicable to distance measurement modules that perform distance measurement, light source modules that cause light to exit omnidirectionally and project images, light sources for rewritable full color papers, and various other apparatuses.

### Configuration Examples of Electronic Circuit Board

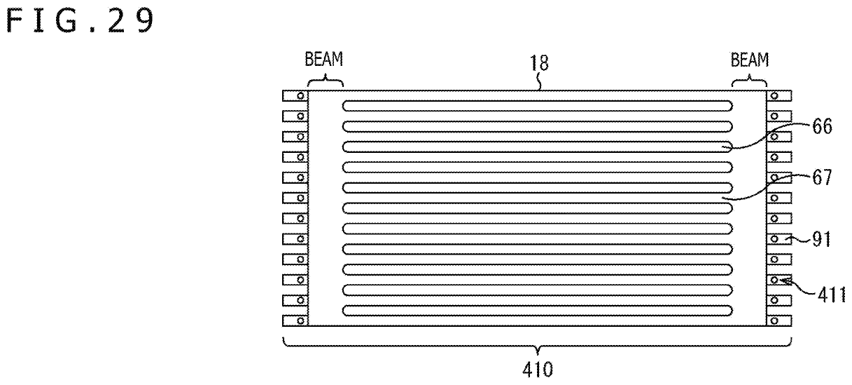

FIG. 29 is a plan view depicting a configuration example of an electronic circuit board to which the present technology is applied.

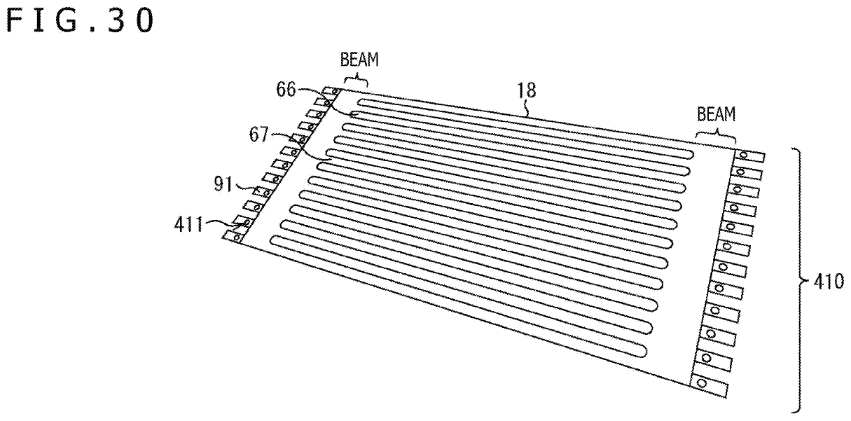

FIG. 30 is a perspective view depicting the configuration example of the electronic circuit board to which the present technology is applied.

In FIG. 29 and FIG. 30, an electronic circuit board 410 is configured similarly to an electronic circuit board included in the light source module 90 in FIG. 15. Because of this, portions in the figure that have counterparts in the case of FIG. 15 are given identical reference characters, and explanations thereof are omitted as appropriate.

The electronic circuit board 410 has the flexible board 18, and a plurality of the reinforcing materials 91.

As explained with reference to FIG. 12, on an approximately rectangular flexible board, the flexible board 18 is formed in a ladder shape having the slits 66 as breaks provided at predetermined intervals. In FIG. 29, the slits 66 are provided to leave unoccupied the left and right ends, in the horizontal direction, of the flexible board 18, and this gives the flexible board 18 a ladder shape which is placed in the depthwise direction.

In FIG. 29 and FIG. 30, the flexible board 18 has one or more slits 66 formed in parallel thereon and thus has a plurality of the strip areas 67 that is formed next to each other in parallel in the lateral direction.

Any desired devices can be arranged in the strip areas 67. For example, by arranging a plurality of the light source chips 10, the light source module 60 in FIG. 12 or the light source module 90 in FIG. 15 can be configured.

On the electronic circuit board 410, the backsides of the strip areas 67 are provided with the reinforcing materials 91 as thin-plate-like plate members so as to support the strip areas 67 along the longitudinal direction of the strip areas 67.

The length of the reinforcing materials 91 in the longitudinal direction is somewhat longer than the length of the flexible board 18 along the longitudinal direction of the strip areas 67. The reinforcing materials 91 are arranged in the strip areas 67 such that the two end sections of each strip area 67 extend somewhat beyond the edges of the flexible board 18.

The length (width) of the reinforcing materials 91 in the lateral direction (almost) matches the length (width) of the strip areas 67 in the lateral direction. It should be noted that the lengths of the reinforcing materials 91 and the strip areas 67 in the lateral direction need not to match, and the ratio between the lengths of the reinforcing materials 91 and the strip areas 67 in the lateral direction can be set as appropriate.

A thickness which is appropriate in accordance with the size of the electronic circuit board 410 or the like, that is, a thickness that allows the reinforcing materials 91 to deform upon application of a certain degree of force and allows the reinforcing materials 91 to maintain the shape after the deformation in a case that the application of the force has been stopped, can be adopted as the thickness of the reinforcing materials 91. For example, in a case that the size (in the widthwise direction and depthwise direction) of the flexible board 18 when the longitudinal direction of the strip areas 67 is placed in the widthwise direction is approximately 80×50 mm, approximately 0.2 to 0.5 mm can be adopted as the thickness of the reinforcing materials 91.

As explained with reference to FIG. 15, the reinforcing materials 91 can include, for example, a metal such as aluminum, stainless, or copper, and the heat dissipation property of the reinforcing materials 91 can be enhanced in a case that the reinforcing materials 91 include aluminum or copper. Other than this, the reinforcing materials 91 can include a material that is more rigid than the flexible board 18, and can be deformed easily.

Note that, in FIG. 29 and FIG. 30, the end sections of the reinforcing materials 91 in the longitudinal direction are provided with positioning holes 411 as a positioning structure for positioning to be performed when the electronic circuit board 410 is deformed.

In addition, on the electronic circuit board 410 in FIG. 29 and FIG. 30, parts of the strip areas 67 formed on the ladder-shaped flexible board 18, that is, portions of the strip areas 67 which correspond to the posts of the ladder, are coupled (continuous) with each other. The portions that couple the strip areas 67 with each other are also referred to as beams. There are two beams in total in the ladder-shaped flexible board 18, one on the left side and the other on the right side.

The thus-configured electronic circuit board 410 can be manufactured by providing the reinforcing materials 91 in the strip areas 67 of the flexible board 18 formed in a ladder shape with adhesion or the like.

As mentioned above, on the electronic circuit board 410 configured by providing the reinforcing materials 91 in (the strip areas 67 of) the flexible board 18, as explained with reference to FIG. 15, the flexible board 18 is deformed along with the reinforcing materials 91, and thus the shape of the flexible board 18 after the deformation is maintained.

Accordingly, the flexible board 18 can be deformed into a desired shape, and the arrangement of devices such as the light source chips 10 conforming to the desired shape can be realized, without damaging the devices arranged (mounted) on the flexible board 18.

For example, by deforming, in advance, the electronic circuit board 410 into a desired shape by using a dedicated jig or the like and adhering, fixing, and attaching, by using an adhesive or the like, the electronic circuit board 410 after the deformation onto a base member including a metal such as aluminum or aluminum nitride, it is possible to manufacture a module on which devices having been mounted on the flexible board 18 is arranged along a surface of the base member.

In particular, the electronic circuit board 410 is useful, for example, in a case that devices and wires are to be arranged on a base member having a curved surface accurately along the curved surface.

For example, in a case that a LiDAR module or a diffusion light source module is to be manufactured, devices such as the light source chips 10 that output (emit) light need to be arranged accurately along a curved surface.

As depicted in FIG. 12 and FIG. 15, according to the electronic circuit board 410, by mounting devices such as the light source chips 10 that output light in the strip areas 67, accurate arrangement of the devices along the curved surface can be realized easily and inexpensively. Note that the devices can be arranged in beam sections, other than the strip areas 67.

Here, in the present specification, curved surfaces are non-planar surfaces in a three-dimensional space and include continuously curved smooth surfaces and discontinuous stepped surfaces. In addition, not a size with which the end sections of the reinforcing materials 91 extend beyond the edges of the flexible board 18 as depicted in FIG. 29 and FIG. 30, but a size with which the end sections of the reinforcing materials 91 are hidden by the flexible board 18 can be adopted as the size of the reinforcing materials 91. In a case that a size with which the end sections of the reinforcing materials 91 are hidden by the flexible board 18 is adopted as the size of the reinforcing materials 91, the positioning holes 411 provided through the end sections of the reinforcing materials 91 are hidden (covered) by the flexible board 18. In this case, holes similar to the positioning holes 411 can be provided at positions on the flexible board 18 that face the positioning holes 411.

### Alternative Configuration Examples of Electronic Circuit Board

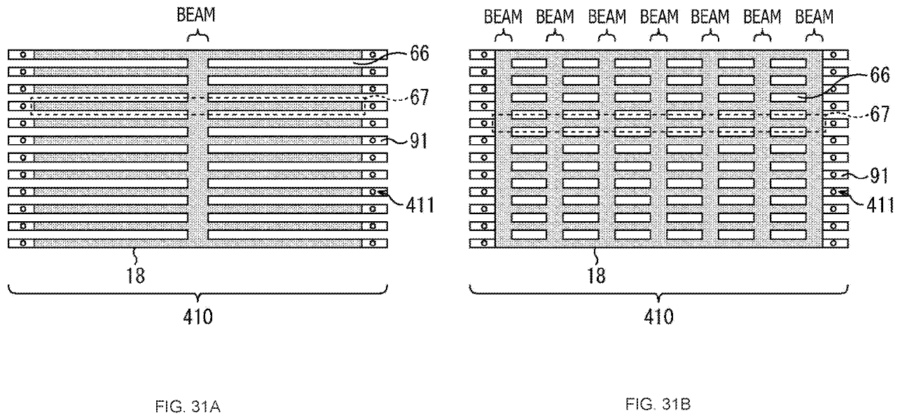

FIG. 31 is a plan view depicting alternative configuration examples of the electronic circuit board to which the present technology is applied.

On the electronic circuit board 410 in FIG. 29 and FIG. 20, the flexible board 18 is formed in a ladder shape. However, the shape of the flexible board 18 is not limited to a ladder shape as long as a plurality of the strip areas 67 that is long in one direction are formed to be continuous at parts (beams) thereof. In addition, in the present specification, areas that are long in one direction are referred to as strip areas for convenience, and the shape of the strip areas 67 is not limited to a strip shape.

A of FIG. 31 depicts a first alternative configuration example of the electronic circuit board to which the present technology is applied.

On the electronic circuit board 410 in A of FIG. 31, the slits 66 are formed such that, when the longitudinal direction of the strip areas 67 is placed in the widthwise direction, there is only one beam at the middle of the flexible board 18 in the widthwise direction, and thus a plurality of the strip areas 67 that is next to each other in parallel are formed.

B of FIG. 31 depicts a second alternative configuration example of the electronic circuit board to which the present technology is applied.

On the electronic circuit board 410 in B of FIG. 31, the slits 66 are formed in a mesh, and thus a plurality of the strip areas 67 that is next to each other in parallel are formed. Furthermore, on the electronic circuit board 410 in B of FIG. 31, when the longitudinal direction of the strip areas 67 is placed in the widthwise direction, one or more beams are formed, in addition to the left and right end sections.

Note that whereas the shape of the slits 66 formed in a mesh in B of FIG. 31 is rectangular, the shape of the slits 66 may be, for example, a shape other than a rectangle such as a circular shape.

In addition, on the flexible board 18, a plurality of the strip areas 67 may not be next to each other in parallel.

Furthermore, on the electronic circuit board 410, other than being provided in one strip area 67, each reinforcing material 91 can be provided across two or three or more adjacent strip areas 67. Accordingly, the number of a plurality of the strip areas 67 formed on the flexible board 18 and the number of a plurality of the reinforcing materials 91 included in the electronic circuit board 410 are different from each other in some cases.

In addition, the electronic circuit board 410 can be configured by using a deformable wiring board other than the flexible board 18.

On a wiring board which is other than the flexible board 18 and included in the electronic circuit board 410, wires to be connected with devices mounted in the strip areas 67 can be provided in the longitudinal direction of the strip areas 67, that is, can be provided between ends on one side and ends on the other side of the strip areas 67 in the longitudinal direction.

Wires of strip areas 67 can be connected with wires of other strip areas 67. Connection between the wires of a plurality of the strip areas 67 can be established via beams.

In addition, on the electronic circuit board 410, the strip areas 67, which is a plurality of areas that is long in one direction, can be formed on the flexible board 18 by providing the slits 66 in the horizontal direction such that the left end and the right end are left unoccupied alternately as depicted in FIG. 13.

<Method of Manufacturing Module by Using Electronic Circuit Board 410>

A method of manufacturing a module (electronic equipment) by using the electronic circuit board 410 is explained below.

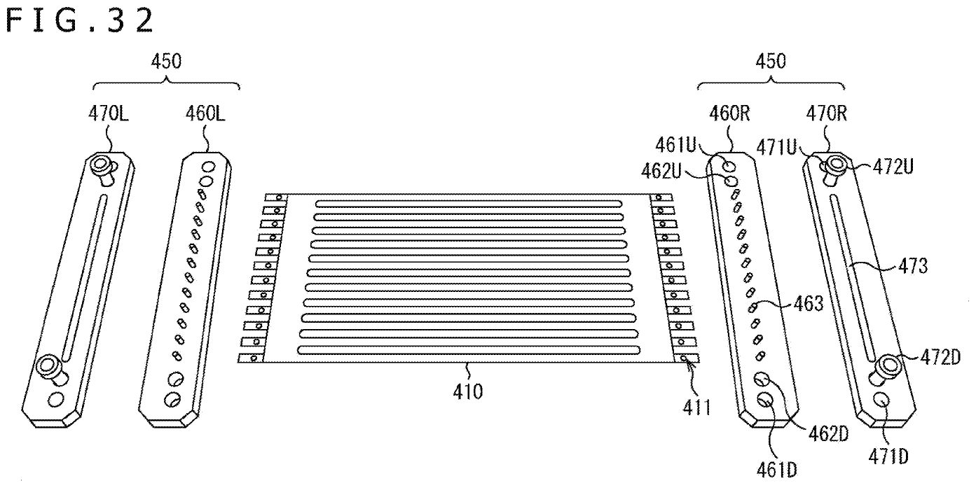

FIG. 32 is a figure depicting a configuration example of primary-curved-surface curving jigs 450 for positionally aligning the reinforcing materials 91 of the electronic circuit board 410, as seen from above and from the front side thereof.

Note that the electronic circuit board 410 is depicted in FIG. 32 along with the primary-curved-surface curving jigs 450.

In FIG. 32, the primary-curved-surface curving jigs 450 have a lower left part 460L and an upper left part 470L, and a lower right part 460R and an upper right part 470R.

The lower left part 460L and the lower right part 460R are left-right symmetrical. Similarly, the upper left part 470L and the upper right part 470R are left-right symmetrical.

Accordingly, the lower right part 460R and the upper right part 470R are explained below, and explanations of the lower left part 460L and the upper left part 470L are omitted as appropriate.

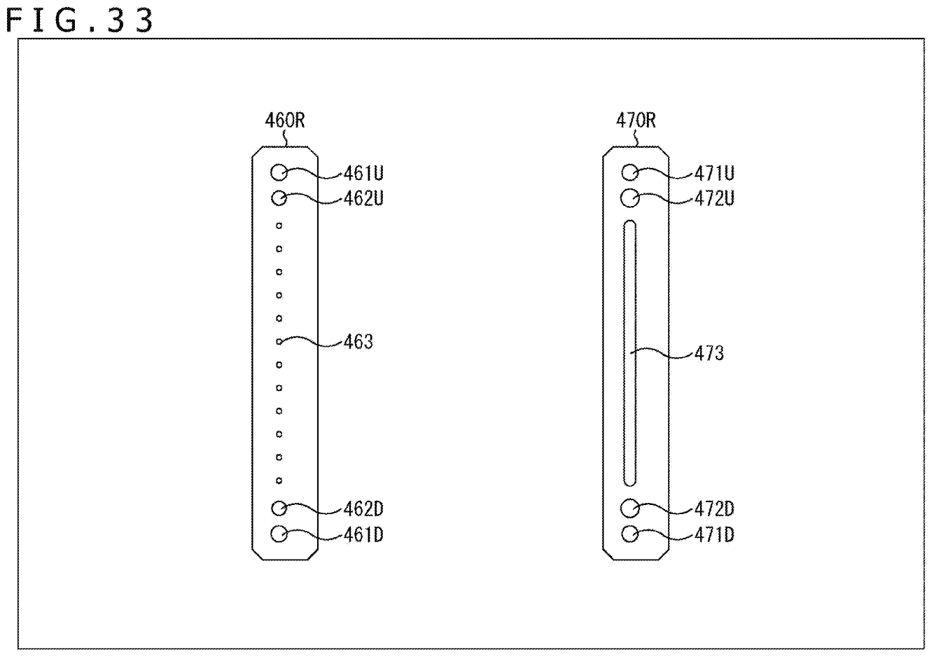

FIG. 33 is a plan view depicting a configuration example of the lower right part 460R and the upper right part 470R.

The lower right part 460R and the upper right part 470R include thin-plate-like metals.

The two end sections of the lower right part 460R in the longitudinal direction are provided with a hole 461U and a hole 461D, respectively.

Portions located slightly inside the hole 461U and the hole 461D are provided with a female screw 462U and a female screw 462D, respectively.

A plurality of pins 463 to be inserted (fit) to positioning holes 411 of the electronic circuit board 410 is provided next to each other between the female screw 462U and the female screw 462D at intervals which correspond to desired arrangement of the reinforcing materials 91 and consequently the strip areas 67. Note that the number of the pins 463 provided is equal to (equal to or larger than) the number of the reinforcing materials 91 of the electronic circuit board 410.

The two end sections of the upper right part 470R in the longitudinal direction are provided with a hole 471U and a hole 471D, respectively.

The hole 471U and the hole 471D are provided at positions to face the hole 461U and hole 461D of the lower right part 460R, respectively, when the upper right part 470R is placed on the lower right part 460R with the lower right part 460R located under the upper right part 470R. The diameters of the hole 471U and the hole 471D are the same as the diameters of the hole 461U and the hole 461D, respectively.

Portions located slightly inside the hole 471U and the hole 471D are provided with a male screw 472U and a male screw 472D, respectively. The male screw 472U and the male screw 472D are provided at positions to face the female screw 462U and female screw 462D of the lower right part 460R, respectively, when the upper right part 470R is placed on the lower right part 460R with the lower right part 460R located under the upper right part 470R. The male screw 472U and the male screw 472D are configured to be screwed into the female screw 462U and the female screw 462D, respectively.

A long hole 473 is provided between the male screw 472U and the male screw 472D. The width of the long hole 473 is slightly larger than the diameter of the pins 463, and the length of the long hole 473 is slightly longer than the distance from a pin 463 at one end in the plurality of pins 463 to a pin 463 at the other end in the plurality of pins 463. Thus, all of the plurality of pins 463 of the lower right part 460R are contained in the long hole 473 of the upper right part 470R when the upper right part 470R is placed on the lower right part 460R with the lower right part 460R located under the upper right part 470R.

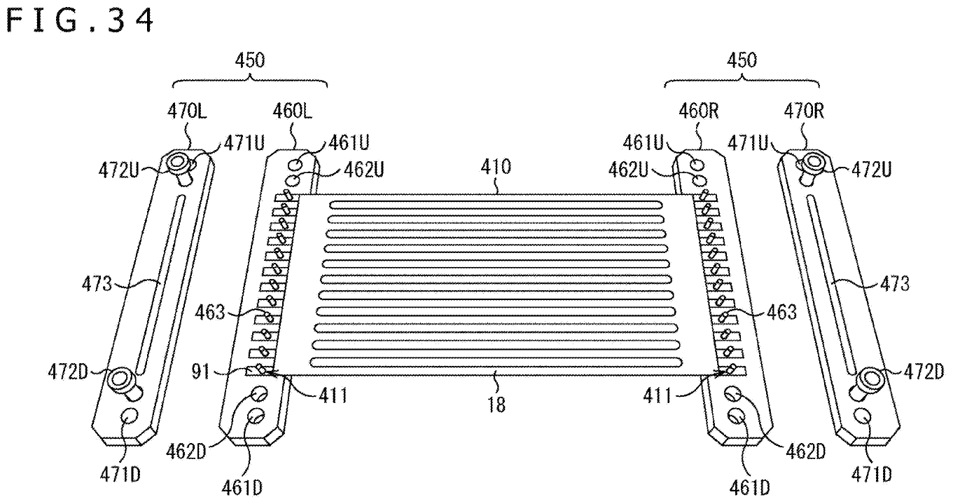

FIG. 34 is a figure depicting a state that the pins 463 of the primary-curved-surface curving jigs 450 and the positioning holes 411 of the electronic circuit board 410 are fit together, as seen from above and from the front side thereof.

As depicted in FIG. 34, in manufacturing of a module by using the electronic circuit board 410, the pins 463 of the lower left part 460L and the positioning holes 411 at the left ends of the reinforcing materials 91 are fit together. In addition, the pins 463 of the lower right part 460R and the positioning holes 411 at the right ends of the reinforcing materials 91 are fit together. Thereby, the electronic circuit board 410 is held by the lower left part 460L and the lower right part 460R, and positioning of the plurality of reinforcing materials 91 is performed at once.

By providing the positioning holes 411 through the reinforcing materials 91 and fitting the positioning holes 411 and the pins 463 of the primary-curved-surface curving jigs 450 together, the plurality of reinforcing materials 91, which is not continuous directly, can be aligned positionally, and the plurality of reinforcing materials 91 can be deformed into a desired shape easily as a whole.

Thereafter, the upper left part 470L is placed on the lower left part 460L with the lower left part 460L being located under the upper left part 470L such that the pins 463 of the lower left part 460L are inserted into the long hole 473 of the upper left part 470L. Similarly, the upper right part 470R is placed on the lower right part 460R with the lower right part 460R being located under the upper right part 470R such that the pins 463 of the lower right part 460R are inserted into the long hole 473 of the upper right part 470R.

Then, the male screw 472U and male screw 472D of the upper left part 470L are screwed into the female screw 462U and female screw 462D of the lower left part 460L, respectively. Thus, the left ends of the reinforcing materials 91 of the electronic circuit board 410 are sandwiched rigidly between the lower left part 460L and the upper left part 470L, and the left end of the electronic circuit board 410 is fixed.

Similarly, the male screw 472U and male screw 472D of the upper right part 470R are screwed into the female screw 462U and female screw 462D of the lower right part 460R, respectively. Thus, the right ends of the reinforcing materials 91 of the electronic circuit board 410 are sandwiched rigidly between the lower right part 460R and the upper right part 470R, and the right end of the electronic circuit board 410 is fixed.

Note that, as depicted in FIG. 12 and FIG. 15, devices such as the light source chips 10 are already mounted (mounted) on the flexible board 18 of the electronic circuit board 410. It should be noted that the devices mounted on the flexible board 18 are not depicted below to avoid complicated figures.

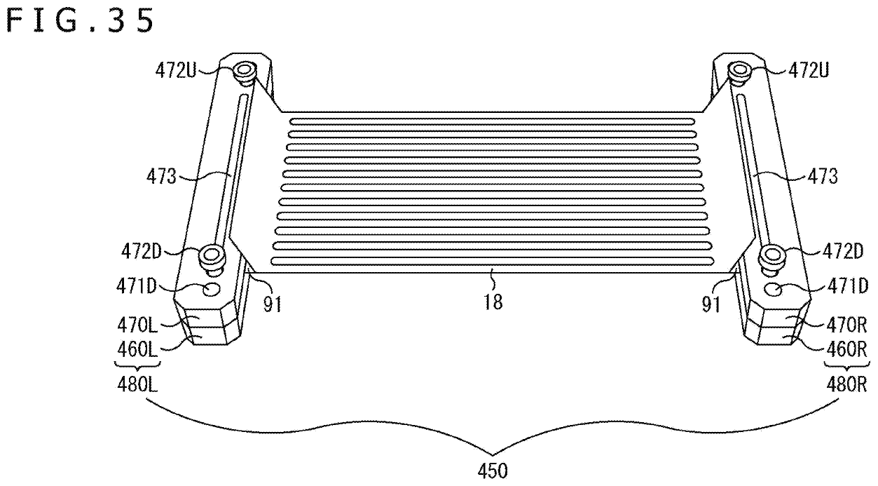

FIG. 35 is a figure depicting a state that the reinforcing materials 91 of the electronic circuit board 410 are sandwiched between the lower left part 460L and the upper left part 470L and between the lower right part 460R and the upper right part 470R as mentioned above, as seen from above and from the front side thereof.

In FIG. 35, the left ends of the reinforcing materials 91 are sandwiched between the lower left part 460L and the upper left part 470L such that the left end of the flexible board 18 is not sandwiched therebetween. Similarly, the right ends of the reinforcing materials 91 are sandwiched between the lower right part 460R and the upper right part 470R such that the right end of the flexible board 18 is not sandwiched therebetween.

As explained with reference to FIG. 34, the male screw 472U and male screw 472D of the upper left part 470L are screwed into the female screw 462U and female screw 462D of the lower left part 460L, respectively, and thus the lower left part 460L and the upper left part 470L become integrated. The hole 461U of the lower left part 460L and the hole 471U of the upper left part 470L in the integrated lower left part 460L and upper left part 470L as a whole form one hole that penetrates from the lower surface of the lower left part 460L to the top surface of the upper left part 470L. The hole 461D of the lower left part 460L and the hole 471D of the upper left part 470L also, as a whole, form one hole that penetrates from the lower surface of the lower left part 460L to the top surface of the upper left part 470L.

Similarly, the male screw 472U and male screw 472D of the upper right part 470R are screwed into the female screw 462U and female screw 462D of the lower right part 460R, and thus the lower right part 460R and the upper right part 470R become integrated. The hole 461U of the lower right part 460R and the hole 471U of the upper right part 470R in the integrated lower right part 460R and upper right part 470R, as a whole, form one hole that penetrates from the lower surface of the lower right part 460R to the top surface of the upper right part 470R. The hole 461D of the lower right part 460R and the hole 471D of the upper right part 470R also, as a whole, form one hole that penetrates from the lower surface of the lower right part 460R to the top surface of the upper right part 470R.

Here, the lower left part 460L and the upper left part 470L that have become integrated by screwing the male screw 472U and male screw 472D of the upper left part 470L into the female screw 462U and female screw 462D of the lower left part 460L, respectively, are also referred to as a left part 480L.

Similarly, the lower right part 460R and the upper right part 470R that have become integrated by screwing the male screw 472U and male screw 472D of the upper right part 470R into the female screw 462U and female screw 462D of the lower right part 460R, respectively, are also referred to as a right part 480R.

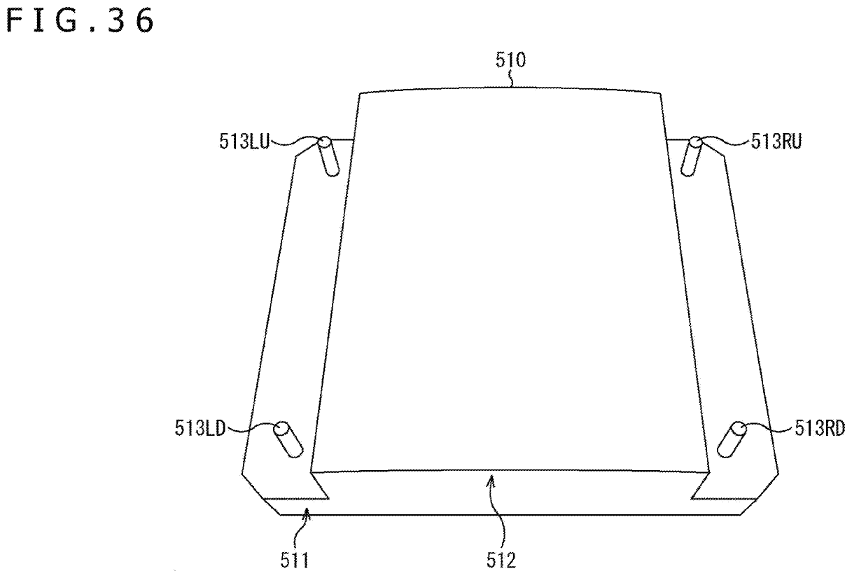

FIG. 36 is a figure depicting a configuration example of a primary-curved-surface model curved surface jig 510 that deforms the electronic circuit board 410, as seen from above and from the front side thereof.

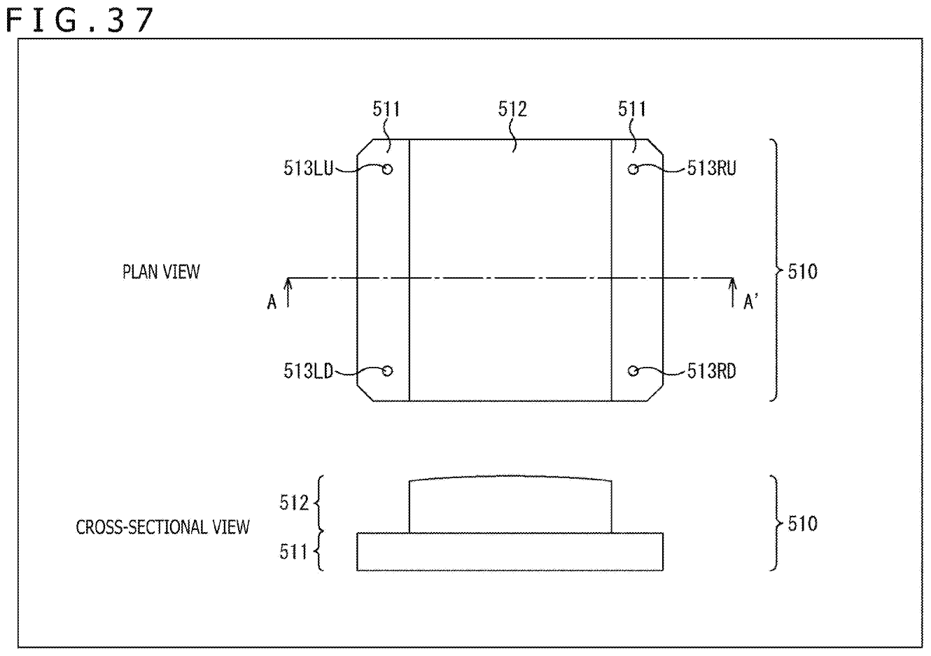

FIG. 37 is a plan view and a cross-sectional view depicting a configuration example of the primary-curved-surface model curved surface jig 510.

Note that the cross-sectional view of FIG. 37 is a cross-sectional view of the primary-curved-surface model curved surface jig 510 taken along line A-A′ in the plan view of FIG. 37.

The primary-curved-surface model curved surface jig 510 has an approximately-protruding cross-section and has a base 511, which is a lower portion of the protruding shape, and a shape forming section 512, which is an upper portion.

The base 511 has a rectangular shape in the plan view, and the shape forming section 512 has a rectangular shape with a width, in the widthwise direction, narrower than the base 511 in the plan view.

The four corners of the rectangular base 511 in the plan view are provided with parallel pins 513LU, 513LD, 513RU, and 513RD.

That is, in the plan view, the upper left, lower left, upper right, and lower right corners of the base 511 are provided with the parallel pins 513LU, 513LD, 513RU, and 513RD, respectively.

The top surface (planar surface) of the shape forming section 512 is a curved surface onto which the electronic circuit board 410 is to be attached and which corresponds to a curved surface of a base member 610 to be mentioned later as the body of a module.

That is, the top surface of the shape forming section 512 is a curved surface like the side surface of a cylinder that is curved gently only about an axis lying in the depthwise direction of FIG. 36. Then, the degree of curvature of the curved surface matches the degree of curvature of the curved surface of the base member 610 about an axis lying in the depthwise direction.

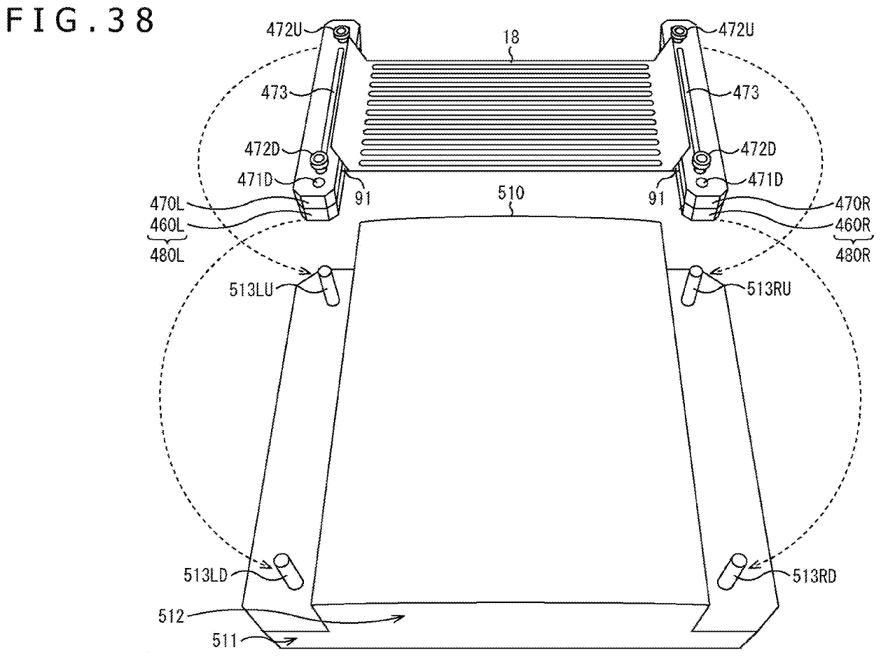

FIG. 38 is a figure depicting a state before the electronic circuit board 410 having been attached to the primary-curved-surface curving jigs 450 is set on the primary-curved-surface model curved surface jig 510.

The state that the electronic circuit board 410 has been attached to the primary-curved-surface curving jigs 450 means a state that the male screw 472U and the male screw 472D have been screwed into the female screw 462U and the female screw 462D, respectively, the male screw 472U and the male screw 472D have been screwed into the female screw 462U and the female screw 462D, respectively, and the reinforcing materials 91 have been sandwiched between the lower left part 460L and the upper left part 470L and between the lower right part 460R and the upper right part 470R.

As explained with reference to FIG. 34 and FIG. 35, in the state that the electronic circuit board 410 has been attached to the primary-curved-surface curving jigs 450, the hole 461U and the hole 471U of the left part 480L and the right part 480R, respectively, form one hole as a whole. Similarly, the hole 461D and the hole 471D of the left part 480L and the right part 480R, respectively, form one hole as a whole.

As represented by dotted arrows in FIG. 38, the parallel pin 513LU is inserted into the one hole formed by the hole 461U and hole 471U of the left part 480L, and the parallel pin 513LD is inserted into the one hole formed by the hole 461D and hole 471D of the left part 480L. In addition, the parallel pin 513RU is inserted into the one hole formed by the hole 461U and hole 471U of the right part 480R, and the parallel pin 513RD is inserted into the one hole formed by the hole 461D and hole 471D of the right part 480R. Thus, the electronic circuit board 410 having been attached to the primary-curved-surface curving jigs 450 is set on the primary-curved-surface model curved surface jig 510.

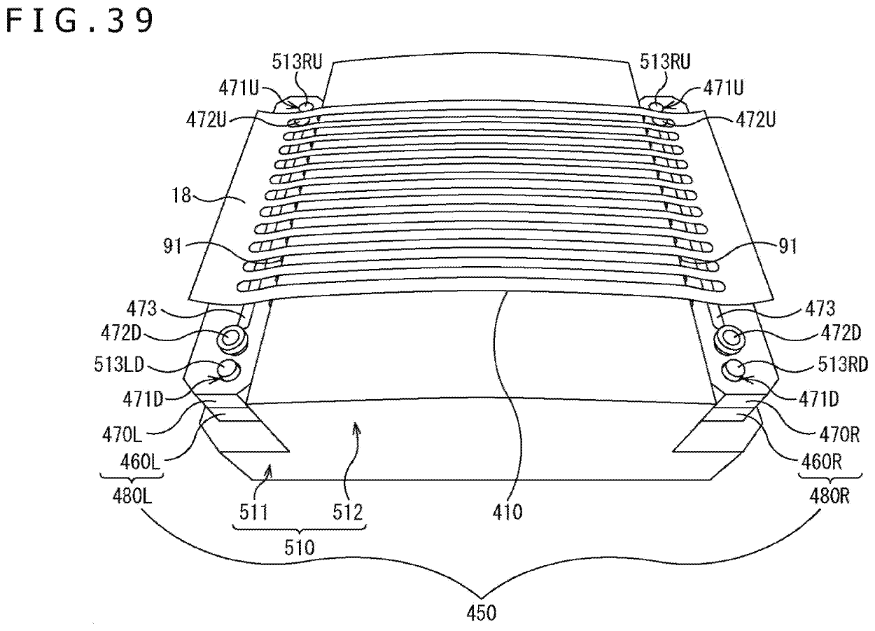

FIG. 39 is a figure depicting a state after the electronic circuit board 410 having been attached to the primary-curved-surface curving jigs 450 is set on the primary-curved-surface model curved surface jig 510.

After the electronic circuit board 410 having been attached to the primary-curved-surface curving jigs 450 is set on the primary-curved-surface model curved surface jig 510, a pressure is applied to the left part 480L and right part 480R of the primary-curved-surface curving jigs 450. The pressure is applied such that the left part 480L and the right part 480R are pressed against the base 511 of the primary-curved-surface model curved surface jig 510.

Thus, each reinforcing material 91 of the electronic circuit board 410 having been attached to the primary-curved-surface curving jigs 450 is pressed against the top surface of the shape forming section 512 of the primary-curved-surface model curved surface jig 510, and is deformed along the curved surface as the top surface. As a result, the electronic circuit board 410 having been attached to the primary-curved-surface curving jigs 450 is deformed along the curved surface as the top surface of the shape forming section 512 of the primary-curved-surface model curved surface jig 510.

Accordingly, the electronic circuit board 410 can be deformed easily along the curved surface as the top surface of the shape forming section 512. In addition, because the electronic circuit board 410 can be deformed without pressing the electronic circuit board 410, destruction of devices mounted on the flexible board 18 of the electronic circuit board 410 due to pressing of the electronic circuit board 410 can be prevented.

Note that it is supposed here that a pressure is applied to the left part 480L and the right part 480R to thereby press the left part 480L and the right part 480R against the base 511 of the primary-curved-surface model curved surface jig 510 and deform the electronic circuit board 410 along the curved surface as the top surface of the shape forming section 512.

It should be noted that deformation of the electronic circuit board 410 may be performed by fixing the left part 480L and the right part 480R, and applying a pressure to the primary-curved-surface model curved surface jig 510 to thereby press the base 511 against the left part 480L and the right part 480R.

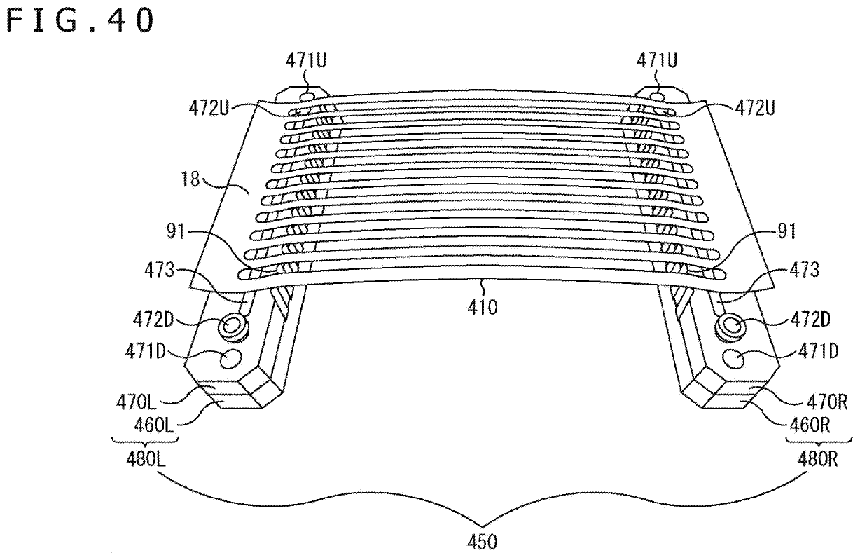

FIG. 40 is a figure depicting the electronic circuit board 410 having been detached from the primary-curved-surface model curved surface jig 510 and having been attached to the primary-curved-surface curving jigs 450 after the deformation of the electronic circuit board 410.

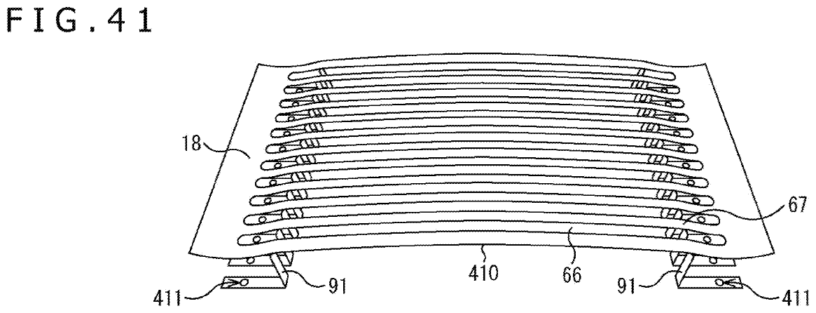

FIG. 41 is a figure depicting the electronic circuit board 410 having been detached from the primary-curved-surface curving jigs 450 in FIG. 40.

As explained with reference to FIG. 39, the electronic circuit board 410 having been attached to the primary-curved-surface curving jigs 450 is set on the primary-curved-surface model curved surface jig 510, and the electronic circuit board 410 is deformed. Thereafter, as depicted in FIG. 40, the electronic circuit board 410 having been attached to the primary-curved-surface curving jigs 450 is detached from the primary-curved-surface model curved surface jig 510.

Furthermore, as depicted in FIG. 41, the electronic circuit board 410 is detached from the primary-curved-surface curving jigs 450.

The detached electronic circuit board 410 maintains the shape of the curved surface as the top surface of the shape forming section 512 of the primary-curved-surface model curved surface jig 510.

Thereafter, the electronic circuit board 410 is attached to a secondary-curved-surface holding jig 520.

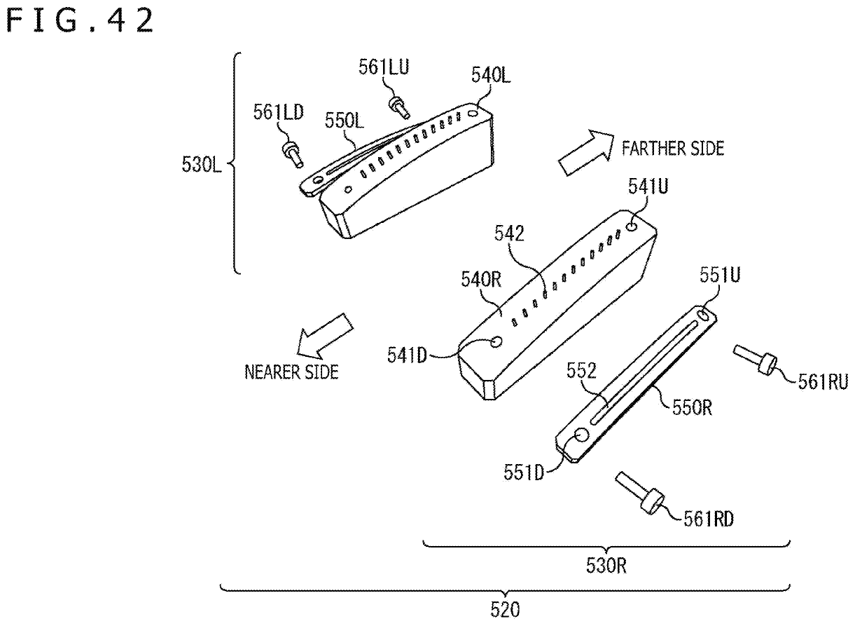

FIG. 42 is a perspective view depicting a configuration example of the secondary-curved-surface holding jig 520.

By attaching the electronic circuit board 410 to the secondary-curved-surface holding jig 520, the electronic circuit board 410 is deformed into a shape identical to the curved surface of the base member 610 to be mentioned later onto which the electronic circuit board 410 is to be attached.

In FIG. 42, the secondary-curved-surface holding jig 520 has a left part 530L and a right part 530R.

The left part 530L has a left base 540L, a left cover 550L, and male screws 561LU and 561LD.

The right part 530R has a right base 540R, a right cover 550R, and male screws 561RU and 561RD.

The left base 540L, left cover 550L, and male screws 561LU and 561LD, and the right base 540R, right cover 550R, and male screws 561RU and 561RD are configured similarly, respectively, and the left part 530L and the right part 530R are left-right symmetrical.

Accordingly, the right part 530R is explained below, and an explanation of the left part 530L is omitted as appropriate.

The right base 540R has an approximately rectangular parallelepiped shape. It should be noted that the top surface of the right base 540R is a curved surface corresponding to the curved surface of the base member 610 onto which the electronic circuit board 410 is to be attached.

That is, the top surface of the right base 540R is a curved surface like the side surface of a cylinder that is curved gently only about an axis lying in the horizontal direction orthogonal to an axis lying in the depthwise direction of FIG. 42. Then, the degree of curvature of the curved surface matches the degree of curvature of the curved surface of the base member 610 about an axis lying in the horizontal direction.

End sections of the top surface of the right base 540R on the nearer side and the farther side are provided with female screws 541D and 541U, respectively.

A plurality of pins 542 to be inserted (fit) to the positioning holes 411 of the electronic circuit board 410 is provided next to each other between the female screws 541U and 541D at intervals which correspond to desired arrangement of the reinforcing materials 91 and consequently the strip areas 67. Note that the number of the pins 542 provided is equal to (equal to or larger than) the number of the reinforcing materials 91 of the electronic circuit board 410.

The right cover 550R includes a thin board having a curved surface. The shape of the curved surface of the thin board as the right cover 550R matches the shape of the curved surface as the top surface of the right base 540R. Accordingly, when the right cover 550R is placed on the top surface of the right base 540R, the right cover 550R and the right base 540R contact each other with no gaps therebetween.

End sections of the right cover 550R on the nearer side and the farther side are provided with holes 551D and 551U, respectively.

The holes 551D and 551U are provided at positions to face the female screws 541D and 541U of the right base 540R, respectively, when the right cover 550R is placed on the top surface of the right base 540R. The diameters of the holes 551D and 551U are slightly larger than the diameters of the female screws 541D and 541U, and additionally are smaller than the diameters of the heads of the male screws 561RD and 561RU.

A long hole 552 is provided in the right cover 550R between the hole 551D and the hole 551U. The width of the long hole 552 is slightly larger than the diameter of the pins 542, and the length of the long hole 552 is slightly longer than the distance from a pin 542 at one end of the plurality of pins 542 to a pin 542 at the other end of the plurality of pins 542. Thus, when the right cover 550R is placed on the top surface of the right base 540R, all of the plurality of pins 542 of the right base 540R penetrate the long hole 552 of the right cover 550R.

The male screws 561RU and 561RD are configured to be screwed into the female screws 541U and 541D.

The electronic circuit board 410 (FIG. 41) after the deformation that has been deformed by using the primary-curved-surface curving jigs 450 and the primary-curved-surface model curved surface jig 510 is attached to the thus-configured secondary-curved-surface holding jig 520.

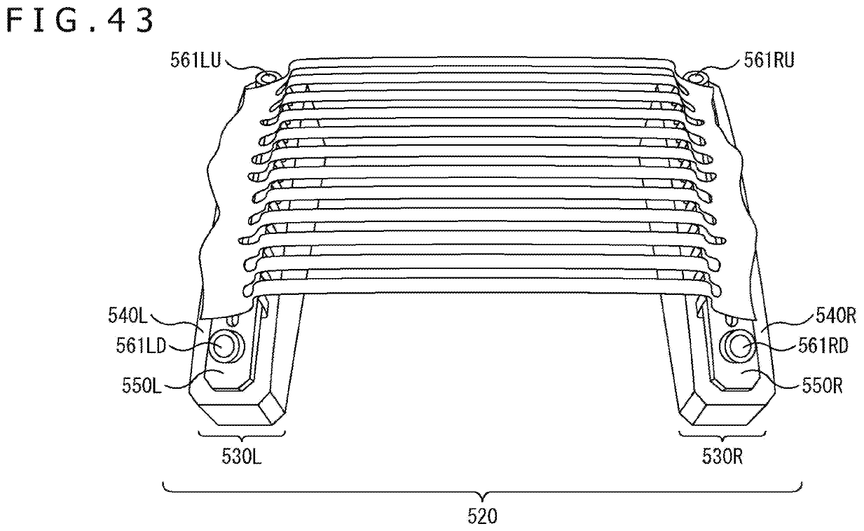

FIG. 43 is a figure depicting a state that the electronic circuit board 410 after the deformation has been attached to the secondary-curved-surface holding jig 520, as seen from above and from the front side thereof.

When the electronic circuit board 410 is attached to the secondary-curved-surface holding jig 520, first, the pins 542 (FIG. 42) of the left base 540L, and the positioning holes 411 (FIG. 41) on the left ends of the reinforcing materials 91 in the electronic circuit board 410 are fit together. In addition, the pins 542 (FIG. 42) of the right base 540R, and the positioning holes 411 (FIG. 41) on the right ends of the reinforcing materials 91 in the electronic circuit board 410 are fit together.

Thereafter, the left cover 550L is placed on the left base 540L such that the pins 542 (FIG. 42) of the left base 540L are inserted into the long hole 552 (FIG. 42) of the left cover 550L. Similarly, the right cover 550R is placed on the right base 540R such that the pins 542 of the right base 540R are inserted into the long hole 552 of the right cover 550R.

Then, the male screws 561LU and 561LD pass through the holes 551U and 551D of the left cover 550L, respectively, and are screwed into the female screws 541U and 541D of the left base 540L, respectively. Thus, the left ends of the reinforcing materials 91 of the electronic circuit board 410 are sandwiched rigidly between the left base 540L and the left cover 550L.

Similarly, the male screws 561RU and 561RD pass through the holes 551U and 551D of the right cover 550R, respectively, and are screwed into the female screw 541U and female screw 541D of the right base 540R, respectively. Thus, the right ends of the reinforcing materials 91 of the electronic circuit board 410 are sandwiched rigidly between the right base 540R and the right cover 550R.

As mentioned above, the left ends and right ends of the reinforcing materials 91 of the electronic circuit board 410 are sandwiched between the left base 540L and the left cover 550L and between the right base 540R and the right cover 550R, respectively. Thus, the reinforcing materials 91 and consequently the electronic circuit board 410 are deformed into a shape conforming to the curved surfaces as the top surfaces of the left base 540L and the right base 540R.

As a result, the electronic circuit board 410 attached to the secondary-curved-surface holding jig 520 is deformed into a shape identical to the curved surface of the base member 610 onto which the electronic circuit board 410 is to be attached.

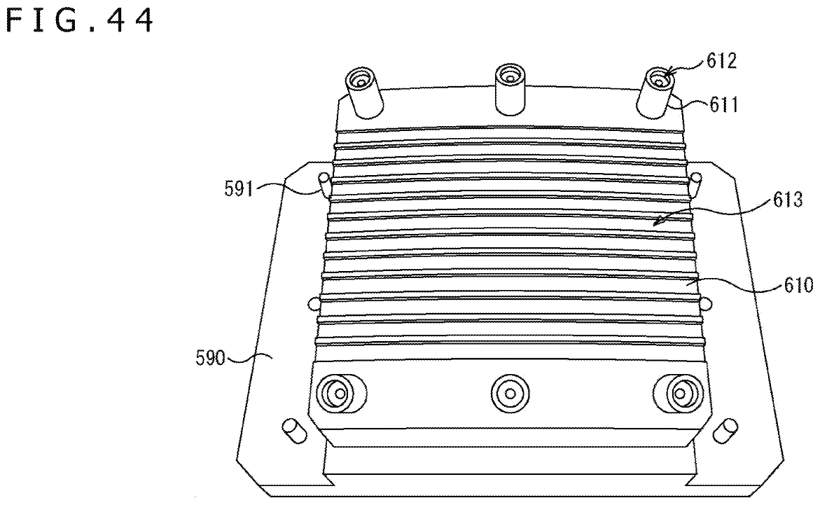

FIG. 44 is a figure depicting a state that the base member 610 has been attached to a secondary-curved-surface holding jig 590, as seen from above and from the front side thereof.

The base member 610 is a pedestal onto which the electronic circuit board 410 is to be fixed, and, as necessary, can include therein a signal processing circuit that processes signals output by devices mounted on the flexible board 18 of the electronic circuit board 410.

The top surface of the base member 610 is formed into a curved surface. The curved surface as the top surface of the base member 610 is a curved surface that is curved gently about an axis lying in the depthwise direction, and additionally is curved gently about an axis lying in the horizontal direction orthogonal to the axis lying in the depthwise direction.

Here, as explained with reference to FIG. 36 and FIG. 37, the curved surface as the top surface of the shape forming section 512 of the primary-curved-surface curving jigs 450 is a curved surface having a curve only about the axis lying in the depthwise direction of the curved surface as the top surface of the base member 610. In addition, as explained with reference to FIG. 42, the curved surfaces as the top surfaces of the left base 540L and right base 540R of the secondary-curved-surface holding jig 520 are curved surfaces having curves only about the axis lying in the horizontal direction of the curved surface as the top surface of the base member 610.

In FIG. 44, each of an end section on the nearer side and an end section on the farther side of the top surface of the base member 610 is provided with three support rods 611. End sections of the support rods 611 have female screws 612 formed therein.

Furthermore, a plurality of shallow grooves 613 that extends in the horizontal direction are formed on the top surface of the base member 610.

The grooves 613 are an example of a positioning structure for positioning to be performed when the electronic circuit board 410 is to be attached. The electronic circuit board 410 is attached to the base member 610 with the reinforcing materials 91 (and the strip areas 67 having the reinforcing materials 91 adhered therein) being fit into the grooves 613.

Other than the grooves 613, for example, a plurality of posts to pass through the slits 66 of the electronic circuit board 410 or the like can be adopted as a positioning structure for positioning to be performed when the electronic circuit board 410 is attached.

In a case that the electronic circuit board 410 attached to the secondary-curved-surface holding jig 520 is to be attached to the base member 610, the base member 610 is attached to the secondary-curved-surface holding jig 590 for positioning.

The secondary-curved-surface holding jig 590 has an approximately flat-plate shape, and four corners of the secondary-curved-surface holding jig 590 are provided with parallel pins 591.

As explained with reference to FIG. 43, the electronic circuit board 410 attached to the secondary-curved-surface holding jig 520 is kept in a state that the electronic circuit board 410 is deformed in a shape identical to the curved surface as the top surface of the base member 610. Such an electronic circuit board 410 is attached to the base member 610 attached to the secondary-curved-surface holding jig 590.

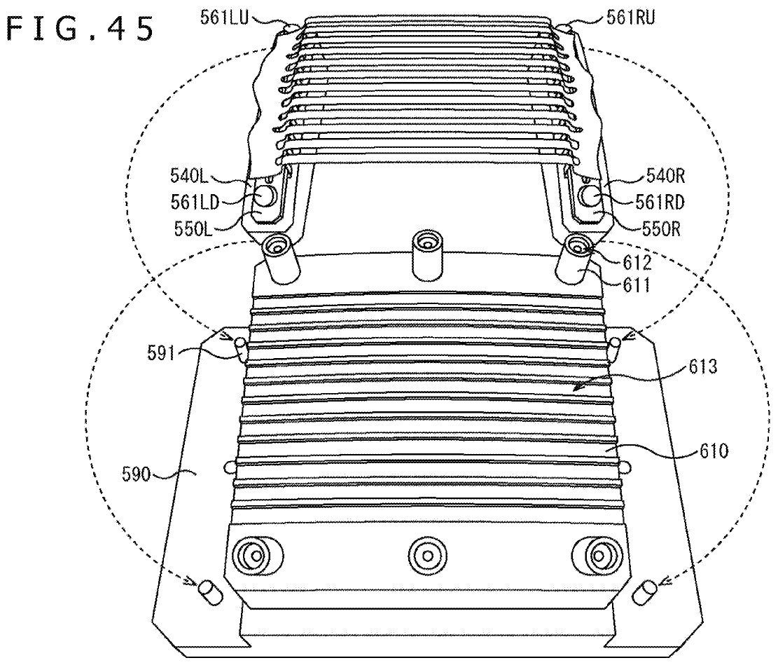

FIG. 45 is a figure depicting a state before the electronic circuit board 410 attached to the secondary-curved-surface holding jig 520 is attached to the base member 610 attached to the secondary-curved-surface holding jig 590.

An adhesive is applied onto the grooves 613 of the base member 610.

Here, end sections of the lower surfaces (bottom surfaces) of the left base 540L and right base 540R of the secondary-curved-surface holding jig 520 are provided with holes which are not depicted and are to fit with the parallel pins 591 of the secondary-curved-surface holding jig 590.

As represented by dotted arrows in FIG. 45, the parallel pins 591 of the secondary-curved-surface holding jig 590 are inserted into the holes at the end sections of the lower surfaces of the left base 540L and the right base 540R, and the secondary-curved-surface holding jig 520 (FIG. 43) is pressed by the secondary-curved-surface holding jig 590.

Thus, the electronic circuit board 410 is attached to the base member 610 with the reinforcing materials 91 (and the strip areas 67) being fit into the grooves 613. The grooves 613 as the positioning structure make it possible to easily fix the electronic circuit board 410 at a desired position of the base member 610.

In a case that the electronic circuit board 410 not provided with the reinforcing materials 91, that is, the flexible board 18, is to be adhered along the curved surface as the top surface of the base member 610, typically, the entire flexible board 18 is pressed from above.

Devices such as the light source chips 10 are mounted on the flexible board 18. Accordingly, pressing the flexible board 18 from above creates a risk of damage to the devices mounted on the flexible board 18.

In addition, even if there is no damage to the devices, a pressurizing force for pressing the flexible board 18 from above causes the ductile flexible board 18 to expand, and the positions of the devices mounted on the flexible board 18 are displaced in some cases.

In contrast to this, the electronic circuit board 410 provided with the reinforcing materials 91 in the strip areas 67 of the flexible board 18 makes it possible to easily mount the electronic circuit board 410 on the curved surface as the curved surface of the base member 610 without directly pressing the flexible board 18. That is, the electronic circuit board 410 can be attached to the curved surface without damaging the devices and additionally without causing the devices to be positionally displaced.

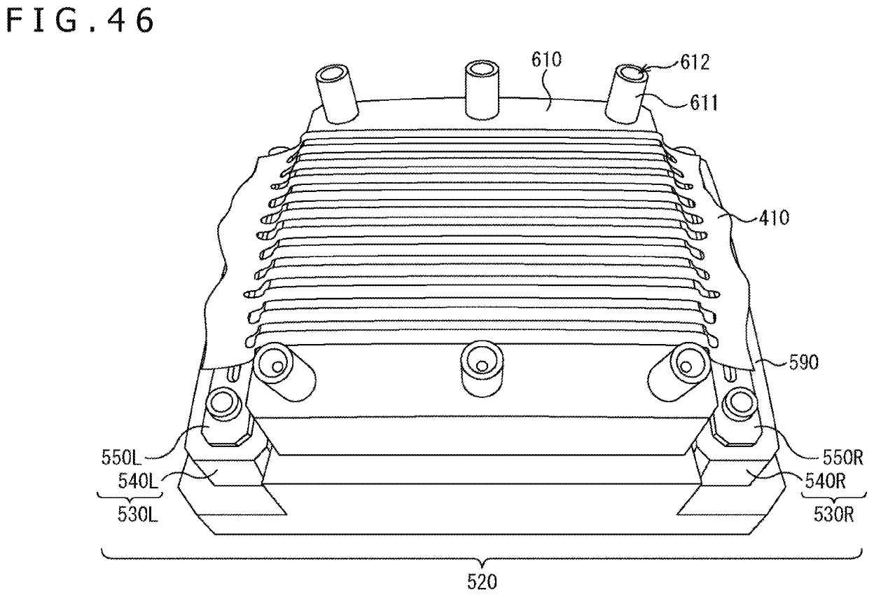

FIG. 46 is a figure depicting a state that the electronic circuit board 410 attached to the secondary-curved-surface holding jig 520 has been attached to the base member 610 attached to the secondary-curved-surface holding jig 590, as seen from above and from the front side thereof.

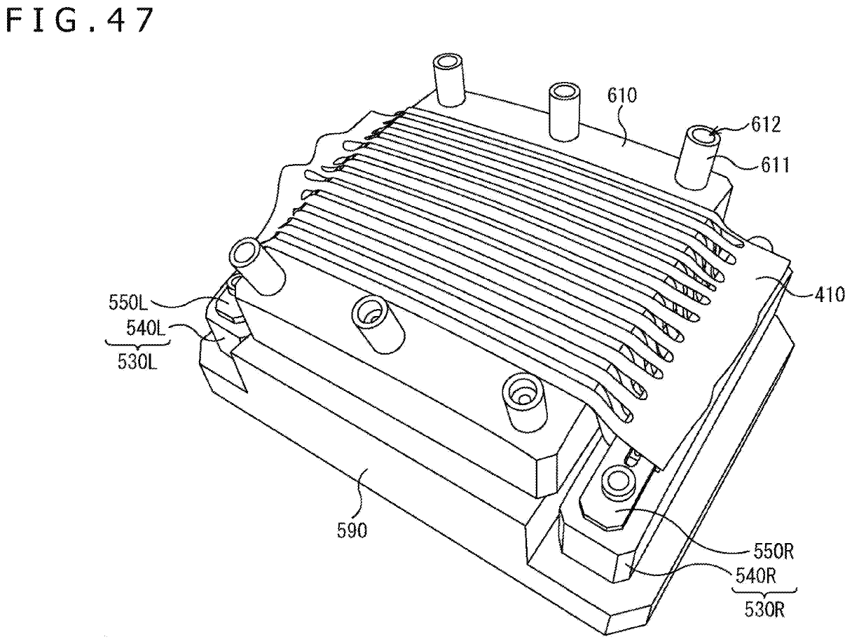

FIG. 47 is a perspective view depicting a state that the electronic circuit board 410 attached to the secondary-curved-surface holding jig 520 has been attached to the base member 610 attached to the secondary-curved-surface holding jig 590.

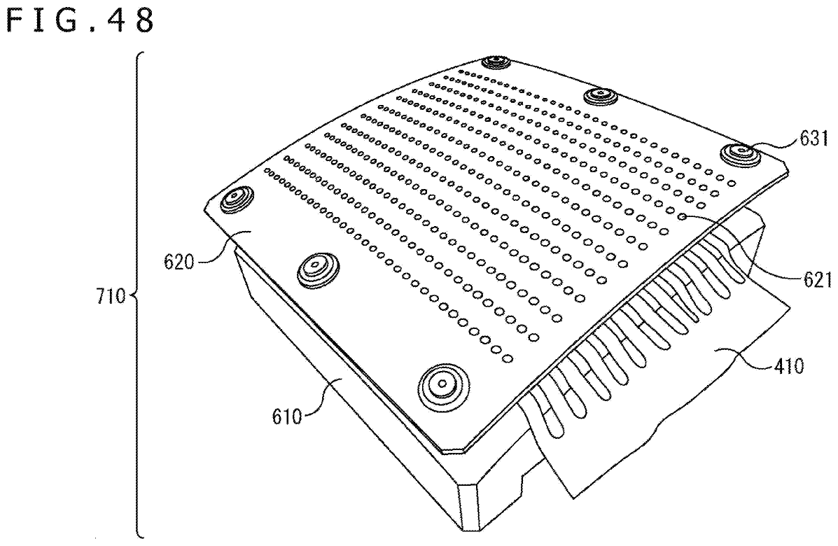

FIG. 48 is a perspective view depicting a configuration example of a module 710 completed by attaching the electronic circuit board 410 to the base member 610.

After the electronic circuit board 410 attached to the secondary-curved-surface holding jig 520 is attached to the base member 610 attached to the secondary-curved-surface holding jig 590, portions of the reinforcing materials 91 that extend beyond both ends of the electronic circuit board 410 are removed by cutting, as necessary.

Note that, in a case that the base member 610 is manufactured by using an inexpensive molded resin or the like, typically, the thermal conductivity is low. In view of this, the reinforcing materials 91 can include a material such as Cu having high thermal conductivity. In this case, it becomes possible to efficiently release heat generated from devices mounted on (the flexible board 18 of) the electronic circuit board 410 to both end sections through the reinforcing materials 91.

After the electronic circuit board 410 is attached to the base member 610, and the portions of the reinforcing materials 91 that extend beyond both ends of the electronic circuit board 410 are removed as necessary, the secondary-curved-surface holding jig 520 and the secondary-curved-surface holding jig 590 are detached. Then, by attaching a dome plate 620 to the base member 610, the module 710 is completed.

The dome plate 620 includes a thin board having a curved surface similar to the top surface of the base member 610.

By screwing male screws 631 into the female screws 612 on end sections of the support rods 611 of the base member 610, the dome plate 620 is fixed to the base member 610.

The dome plate 620 is provided with a plurality of holes 621. In a case that accurate positioning has been performed, the holes 621 and devices mounted on (the flexible board 18 of) the electronic circuit board 410 face each other when the dome plate 620 has been fixed to the base member 610.

The holes 621 are provided with lenses (expand lenses) which are not depicted. For example, in a case that devices mounted on the electronic circuit board 410 are the light source chips 10, light emitted by the light source chips 10 exits from the holes 621 that the light source chips 10 face, via the lenses provided in the holes.

The thus-configured module 710 can be used as, for example, a light source module of a LiDAR or the like.

### Configuration Example of LiDAR to which Present Technology is Applied

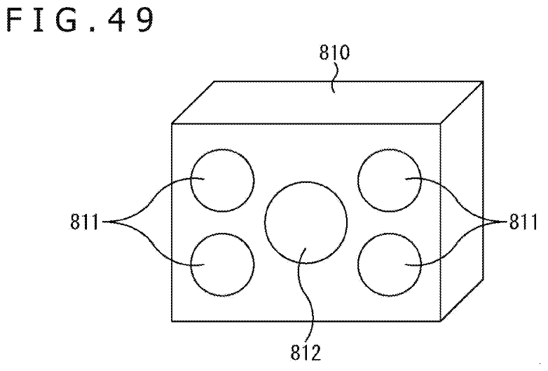

FIG. 49 is a perspective view depicting an overview of a configuration example of a LiDAR to which the present technology is applied.

In FIG. 49, a LiDAR 810 is configured in an approximately rectangular parallelepiped shape, and has, on the front face, four transmitting sections 811 and one receiving section 812.

The four transmitting sections 811 are arranged at the four corners of the front face of the LiDAR 810, and the receiving section 812 is arranged at the middle of the front face of the LiDAR 810 such that the receiving section 812 is surrounded by the four transmitting sections 811.

The transmitting section 811 emits light.

The receiving section 812 receives (light including) light that is emitted at the transmitting sections 811 and returns after being reflected off of a subject, and performs photoelectric conversion into an electric signal corresponding to the light amount of the received light.

At the LiDAR 810, the distance to the subject is measured (distance measurement is performed) in accordance with the electric signal obtained by the photoelectric conversion of the receiving section 812.

Note that, for example, one, two, three, or five or more transmitting sections 811, other than four transmitting sections 811, can be provided in the LiDAR 810.

In addition, the number of receiving sections 812 provided in the LiDAR 810 can be larger than one.

In a case that one transmitting section 811 and one receiving section 812 are provided in the LiDAR 810, the transmitting section 811 and the receiving section 812 can be provided such that, for example, the transmitting section 811 and the receiving section 812 are next to each other in the left and right direction or in the up and down direction.

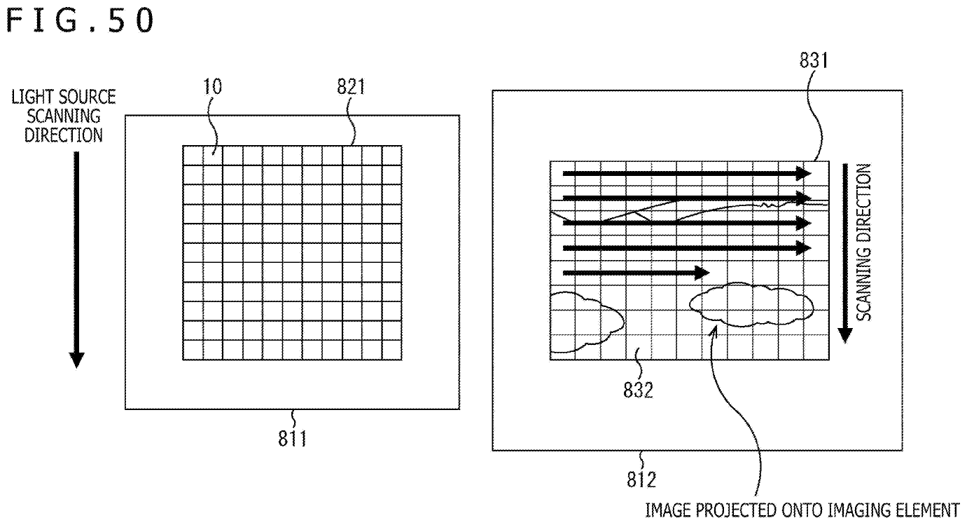

FIG. 50 is a figure depicting a configuration example of a transmitting section 811 and a receiving section 812.

The transmitting section 811 has a light source module 821.

For example, the light source module 821 is configured by attaching, to the base member 610, the electronic circuit board 410 having a plurality of the light source chips 10 mounted (mounted) thereon, as in the module 710 in FIG. 48.

In the light source module 821, a plurality of the light source chips 10 is mounted such that the plurality of light source chips 10 is next to each other in the longitudinal direction of the strip areas 67, and thus, as a whole, the plurality of light source chips 10 is arranged in an approximate grid and approximately two-dimensionally.

Note that only the light source chips 10 are depicted about the light source module 821 in FIG. 50.

In the thus-configured light source module 821, the light source chips 10 are scanned, for example, starting from the uppermost line downward one (horizontal) line at a time. Thus, the light source chips 10 emit light sequentially starting from the uppermost line downward one line at a time.

As mentioned above, by not causing all of the light source chips 10 to emit light simultaneously in the light source module 821, but by causing the light source chips 10 to emit light one line at a time, it is possible to attempt to reduce electric power consumption. Furthermore, it is possible to attempt to increase the output power of light in accordance with the laser safety standards.

The receiving section 812 includes, for example, an imaging element 831 such as a CMOS (complementary metal oxide semiconductor) (image) sensor.

The imaging element 831 includes, for example, pixels 832 that have photoelectric converting elements such as SPADs (single photon avalanche diodes), and are arranged in an approximate grid and approximately two-dimensionally. The pixels 832 receive incident light (reflection light from a subject, etc.), and perform photoelectric conversion into electric signals corresponding to the light amounts of the received light.

In the thus-configured imaging element 831, the pixels 832 are scanned, for example, starting from the uppermost line downward one line at a time. Thus, the electric signals obtained at the pixels 832 are read out sequentially starting from the uppermost line downward one line at a time.

In the LiDAR 810, a line of light source chips 10 of the light source module 821, and a line of pixels 832 of the imaging element 831 are associated with each other, and light emission of the light source chips 10 in each line and read operation of electric signals from the pixels 832 in each line are performed synchronously.

For example, in a case that the number of lines of the light source chips 10 and the number of lines of the pixels 832 are the same, an n-th line (counted from the top line) of the light source chips 10 and an n-th line of the pixels 832 are associated with each other. Then, in relation to emission of light of light source chips 10 in the n-th line, electric signals from pixels 832 in the n-th line that have received reflection light of the light from a subject are read out.

In addition, for example, in a case that the number of lines of the pixels 832 is twice as large as the number of lines of the light source chips 10, the n-th line of the light source chips 10, and two lines, a 2n−1-th line and a 2n-th line, of the pixels 832 are associated with each other. Then, in relation to emission of light of light source chips 10 in the n-th line, electric signals from pixels 832 in the two lines, the 2n−1-th line and the 2n-th line, which have received reflection light of the light from a subject are read out sequentially.

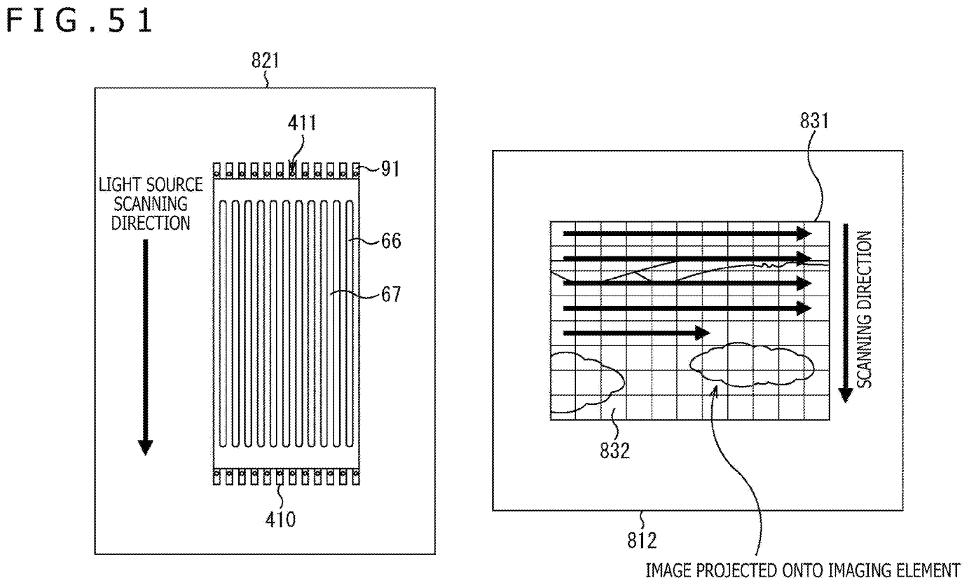

FIG. 51 is a figure for explaining a positional relationship, in the LiDAR 810, between the imaging element 831 and the electronic circuit board 410 having the light source chips 10 mounted thereon.

The electronic circuit board 410 and the imaging element 831 can be arranged such that the longitudinal direction of the strip areas 67, and lines along which the pixels 832 are scanned are approximately orthogonal to each other.

Here, in the light source module 821, by mounting a plurality of the light source chips 10 in each strip area 67 of the electronic circuit board 410, the plurality of light source chips 10 is arranged in an approximate grid and approximately two-dimensionally.

It is supposed now that an electric power supply line and a GND line are placed along the longitudinal direction in each strip area 67 of the light source module 821, and electric power is supplied from end sections of the strip area 67 to a plurality of the light source chips 10 mounted in the strip area 67.

In this case, when the electronic circuit board 410 and the imaging element 831 are arranged such that the longitudinal direction of the strip areas 67 and the lines along which the pixels 832 are scanned become approximately parallel with each other, if the light source chips 10 are caused to emit light sequentially starting from the uppermost line downward one line at a time, electric currents flowing through the electric power supply lines and the GND lines placed in the strip areas 67 is concentrated at one strip area 67 at a time.

That is, in a case that the electronic circuit board 410 and the imaging element 831 are arranged such that the longitudinal direction of the strip areas 67, and the lines along which the pixels 832 are scanned become approximately parallel with each other, in the light source module 821, all of a plurality of the light source chips 10 mounted in each strip area 67 emit light simultaneously.

Accordingly, the electric current that is caused to flow from both ends of the strip area 67 needs to be adequate for causing all of the plurality of light source chips 10 mounted in the strip area 67 to emit light simultaneously.

On the other hand, in a case that the electronic circuit board 410 and the imaging element 831 are arranged such that the longitudinal direction of the strip areas 67 and the lines along which the pixels 832 are scanned become approximately orthogonal to each other, if the light source chips 10 are caused to emit light sequentially starting from the uppermost line downward one line at a time, electric currents flowing through the electric power supply lines and the GND lines placed in the strip areas 67 are distributed to the strip areas 67.

That is, in this case, in the light source module 821, the plurality of light source chips 10 mounted in the strip areas 67 emit light sequentially in the longitudinal direction of the strip areas 67. Accordingly, in light emission of light source chips 10 in each line, only one in a plurality of the light source chips 10 mounted in each strip area 67 emits light.

Therefore, the electric current that is caused to flow from both ends of a strip area 67 only has to be adequate for causing only one in a plurality of the light source chips 10 mounted in the strip area 67 to emit light. Accordingly, electric currents that are caused to flow through an electric power supply line and a GND line placed in each strip area 67 can be reduced.

<Devices to be Mounted on Electronic Circuit Board 410>

Whereas it has been supposed thus far that the light source chips 10 are mounted on (the flexible board 18 of) the electronic circuit board 410, various devices other than the light source chips 10 can be mounted (mounted) on the electronic circuit board 410.

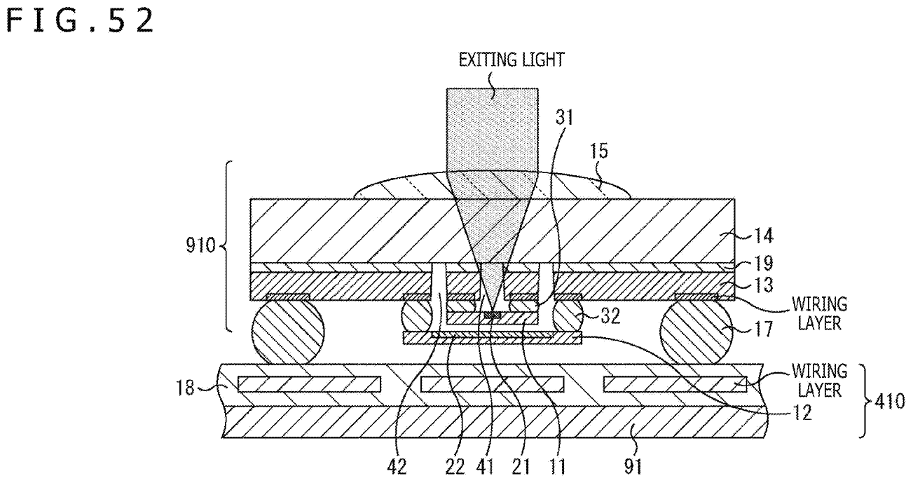

FIG. 52 is a cross-sectional view depicting a configuration example of a light-receiving/emitting chip as a device that can be mounted on the electronic circuit board 410.

In FIG. 52, a light-receiving/emitting chip 910 has a configuration having a functionality of receiving light, in addition to functionalities of the light source chip 10 in FIG. 1. Accordingly, portions in FIG. 52 that have counterparts in the light source chip 10 in FIG. 1 are given identical reference characters, and explanations thereof are omitted as appropriate below.

The light-receiving/emitting chip 910 has the light-emitting board 11, a light-receiving board 12, the circuit board 13, the transmissive board 14, and the lens 15.

The light-receiving board 12 includes a single light-receiving element 22 or two-dimensionally arranged light-receiving elements 22. The light-receiving element 22 includes, for example, a photoelectric converting element such as a PD (photodiode), an APD (avalanche photodiode), or an SPAD (single-photon avalanche diode).

The circuit board 13 includes a light emission control section, a transimpedance amplifier (TIA), a time measuring section (TDC: Time to Digital Converter), a distance calculating section, a serializer, a deserializer, and the like, which are not depicted. The light emission control section controls light emission of the light-emitting element 21. The time measuring section measures the length of time that elapses after irradiation of light (exiting light) from the light-emitting element 21 and reception of light by the light-receiving element 22 (reflection light that returns due to reflection of the exiting light of the light-emitting element 21 off of a subject). On the basis of the length of time measured by the time measuring section, the distance calculating section calculates a distance to the subject irradiated with the light.

The transmissive board 14 is stacked on the circuit board 13. The transmissive board 14 is adhered to the circuit board 13 by an adhesion layer 19 or the like including an adhesive. Note that the adhesion layer 19 is omitted in the light source chip 10 in FIG. 1 and the like.

The lens 15 is formed on the transmissive board 14. The lens 15 can include resin, acrylic, quartz, or the like.

The light-emitting board 11, the light-receiving board 12, and the circuit board 13 are arranged in order of the circuit board 13, the light-emitting board 11, and the light-receiving board 12 as seen from the lens 15. It should be noted that the positions of the light-emitting board 11 and the light-receiving board 12 may be reversed.

The light-emitting board 11 is connected to the circuit board 13 via the first bumps (solder bumps) 31.

In a case that the light-emitting board 11, the light-receiving board 12, and the circuit board 13 are arranged in order of the circuit board 13, the light-emitting board 11, and the light-receiving board 12, the light-receiving board 12 is connected to the circuit board 13 via third bumps 32 having diameters larger than the first bumps 31.

The light-receiving/emitting chip 910 is a device formed by stacking and integrating the light-emitting element 21, the light-receiving element 22 and the lens 15 approximately coaxially.

The lens 15 is a collimate lens that converts light emitted by the light-emitting element 21 (e.g. a VCSEL) into exiting light which is collimated light. Simultaneously, the lens 15 functions also as a lens that condenses reflection light to the light-receiving element 22 (PD).

The positional relationship between the light-receiving board 12 and the lens 15 is set such that reflection light received by the light-receiving board 12 is slightly defocused and blurred. This is because, in FIG. 52, the light-emitting board 11 is arranged at a middle portion of the light-receiving surface of (the light-receiving element 22 of) the light-receiving board 12, reflection light does not enter the middle portion of the light-receiving surface, and therefore the light reception efficiency of the reflection light is enhanced by intentionally defocusing and blurring the reflection light.

As another method of enhancing the light reception efficiency of reflection light, there is a method of contriving the shape of the lens 15. For example, a middle section of the lens 15 to be hit by light emitted by the light-emitting element 21 is configured in a shape that functions as a collimate lens for exiting light. Portions outside the middle section of the lens 15 (peripheral sections of the lens 15) are configured such that the reflection light hits the light-receiving element 22 in a defocused state.

In the light-receiving/emitting chip 910, the circuit board 13 is arranged on a side where light exits from the light-emitting board 11 and on a side where light (reflection light) to be received by the light-receiving board 12 enters. For example, by configuring the circuit board 13 as a very thin board by using Si, almost the entire light is transmitted through the circuit board 13, but the circuit board 13 lowers the transmission efficiency of light to no small extent. In view of this, in order to cause a larger amount of light to be transmitted, openings 41 and 42 can be formed through portions of the circuit board 13 that correspond to the light-emitting element 21 and to the light-receiving element 22, respectively.

By mounting the thus-configured light-receiving/emitting chip 910 on, for example, the electronic circuit board 410, a block having functionalities of both the transmitting section 811 and the receiving section 812 of the LiDAR 810 in FIG. 49 can be configured.

The mounting of the light-receiving/emitting chip 910 on the electronic circuit board 410 can be performed by, for example, Flip Chip to electrically connect (the wiring layer of) the circuit board 13 of the light-receiving/emitting chip 910 and (the wiring layer of) the flexible board 18 by using the second bumps 17.

Note that mounting of the light source chips 10, the light-receiving/emitting chip 910, and other devices on the electronic circuit board 410 can be performed by mounting methods other than Flip Chip, for example, by wire bonding or the like.

Here, a device like the light source chip 10 or the light-receiving/emitting chip 910 having a configuration in which the light-emitting board 11, the light-receiving board 12, or both the light-emitting board 11 and the light-receiving board 12 are electrically connected to the circuit board 13 stacked on the transmissive board 14 is also referred to as Mixcel.

In the thus-configured Mixcel, light emitted by the light-emitting board 11 exits by being transmitted through the transmissive board 14. In addition, in the Mixcel, light that enters by being transmitted through the transmissive board 14 is received at the light-receiving board 12.

The Mixcel can be configured as a light-emitting device that emits light, by having only the light-emitting board 11 of the light-emitting board 11 and the light-receiving board 12, like the light source chip 10.

In addition, the Mixcel can be configured as a light-receiving/emitting device that emits light, and receives reflection light of the light, by having both the light-emitting board 11 and the light-receiving board 12, like the light-receiving/emitting chip 910.

Other than these, the Mixcel can be configured as a light-receiving device that receives light, by having only the light-receiving board 12 of the light-emitting board 11 and the light-receiving board 12.

A device having a configuration other than the configuration of the Mixcel can be adopted as a light-emitting device, a light-receiving device, and a light-receiving/emitting device to be mounted on the electronic circuit board 410.

In addition, other than devices like a light-emitting device, a light-receiving device, and a light-receiving/emitting device that output (emit) light or sense (receive) light, devices that output or sense electromagnetic waves with a certain wavelength such as radio waves other than light can be mounted on the electronic circuit board 410.

That is, output devices that output electromagnetic waves such as light or radio waves, sensing devices that sense electromagnetic waves or output/sensing devices that output and sense electromagnetic waves can be mounted on the electronic circuit board 410.

In addition, both the output devices and the sensing devices can be mounted on the electronic circuit board 410.

In a case that both the output devices and the sensing devices are mounted on the electronic circuit board 410, for example, the output devices and the sensing devices can be arranged in two areas formed by dividing the flexible board 18 into two. Other than this, for example, the output devices and the sensing devices can be arranged in every other line or in every other column or can be arranged in a checkered pattern (check pattern) or the like by being arranged in every other device.

Here, examples of the output devices that output (transmit) radio waves and the sensing devices that sense (receive) radio waves include, for example, VOR (VHF omni-directional radio range) transmitters, receivers, or the like used for a three-dimensional sensing module that senses the three-dimensional position of an aircraft or the like.

By mounting the VOR transmitters and receivers on the electronic circuit board 410, a small-sized, lightweight, low-cost three-dimensional sensing module can be manufactured.

If a size reduction, a weight reduction, and a cost reduction of the three-dimensional sensing module are realized, the three-dimensional module can be mounted on a vehicle such as an automobile or a bicycle, and also can be mounted on mobile equipment such as a smartphone or a smartwatch carried by a pedestrian. Thus, it is possible to prevent a minor collision before it happens by using the vehicle or the mobile equipment to grasp the relative position of a vehicle or a pedestrian that is present nearby and notify the presence of the vehicle or the pedestrian, and the like.

Note that embodiments of the present technology are not limited to the embodiments mentioned above, but can be changed in various manners within the scope not deviating from the gist of the present technology.

In addition, advantages described in the present specification are mentioned merely for illustrative purposes, and are not the sole advantages. There may be other advantages.

Note that the present technology can have the following configurations.

<1>

An electronic circuit board including:
a deformable wiring board having a plurality of areas that is long in one direction and is formed to be partially continuous with each other; and
a deformable plate-like plate member that is provided in the plurality of areas, and is more rigid than the wiring board.

<2>

The electronic circuit board according to <1>, in which the plate member is provided in each of the areas.

<3>

The electronic circuit board according to <1> or <2>, including:
a positioning structure for positioning.

<4>

The electronic circuit board according to any one of <1> to <3>, in which devices that output electromagnetic waves, devices that sense electromagnetic waves, devices that output and sense electromagnetic waves, or devices that output electromagnetic waves and devices that sense electromagnetic waves are mounted on the wiring board.

<5>

The electronic circuit board according to <4>, in which a plurality of devices that is included in the devices mounted on the wiring board and is capable of outputting light is configured to output light sequentially in a longitudinal direction.

<6>

The electronic circuit board according to any one of <1> to <5>, in which wires are provided in a longitudinal direction of the areas.

<7>

The electronic circuit board according to <6>, in which the wires of the respective areas are connected with each other.

<8>

The electronic circuit board according to any one of <1> to <7>, in which the plate member includes a metal.

<9>

A base member including:
a curved surface on which a positioning structure for positioning the electronic circuit board according to any one of <1> to <8> is formed and the electronic circuit board is to be attached.

<10>

The base member according to <9>, in which a groove to which the plate member fits is formed as the positioning structure.

<11>

Electronic equipment including:
the electronic circuit board according to any one of <1> to <8>; and
the base member according to <9> or <10> to which the electronic circuit board is attached.

<12>

The electronic equipment according to <11>, further including an imaging element having pixels that are to be scanned one line at a time, in which
the electronic circuit board and the imaging element are arranged such that the longitudinal direction of the areas, and lines along which the pixels are scanned become approximately orthogonal.

<13>

An electronic equipment manufacturing method including:
sandwiching and fixing end sections of the plate member of the electronic circuit board according to any one of <1> to <8> by using jigs, pressing the electronic circuit board against a curved surface corresponding to a curved surface of a base member, and deforming the electronic circuit board; and
attaching the electronic circuit board after the deformation to the curved surface of the base member.

<14>

An electronic circuit board manufacturing method including providing, in a plurality of areas that is long in one direction and is formed on a deformable wiring board such that the plurality of areas is partially continuous with each other, a deformable plate-like plate member that is more rigid than the wiring board.

### REFERENCE SIGNS LIST

10: Light source chip
11: Light-emitting board
12: Light-receiving board
13: Circuit board
14: Transmissive board
15: Lens
17: Second bump
18: Flexible board
19: Adhesion layer
21: Light-emitting element
22: Light-receiving element
31: First bump
32: Third bump
41, 42: Opening
60: Light source module
62: Control element
63: Interface element
65: Connection wire
66: Slit
67: Strip area
70: Light source module
80, 90: Light source module
91: Reinforcing material
111: Flexible base
112: Main bearing
113: Rotary contact
114: Micro DC motor
115: Main gear
116: Main shaft
117: Transparent cover
131: Resin molded lens
201, 211, 221: Lens array
231: Heat dissipating body
241: Core body
251: Under-filler material
310: Distance measurement module
311: Substrate
312, 313: Base member
314: Light-receiving section
321: Cooling mechanism
330, 340, 350, 360: Light source module
361: Outer rib section
371: Base member
372: Lens array
373: Cover
410: Electronic circuit board
411: Positioning hole
450: Primary-curved-surface curving jig
460L: Lower left part
460R: Lower right part
461D, 461U: Hole
462D, 462U: Female screw
463: Pin
470L: Upper left part
470R: Upper right part
471D, 471U: Hole
472D, 472U: Male screw
473: Long hole
480L: Left part
480R: Right part
510: Primary-curved-surface model curved surface jig
511: Base
512: Shape forming section
513LD, 513LU, 513RD, 513RU: Parallel pin
520: Secondary-curved-surface holding jig
530L: Left part
530R: Right part
540L: Left base
540R: Right base
541D, 541U: Female screw
542: Pin
550L: Left cover
550R: Right cover
551D, 551U: Hole
552: Long hole
561LD, 561LU, 561RD, 561RU: Male screw
590: Secondary-curved-surface holding jig
591: Parallel pin
610: Base member
611: Support rod
612: Female screw
620: Dome plate
621: Hole
710: Module
810: LiDAR
811: Transmitting section
812: Receiving section
821: Light source module
831: Imaging element
832: Pixel
910: Light-receiving/emitting chip

1. An electronic circuit board comprising:
a deformable wiring board having a plurality of areas that is long in one direction and is formed to be partially continuous with each other; and
a deformable plate-like plate member that is provided in the plurality of areas and is more rigid than the wiring board.

2. The electronic circuit board according to claim 1, wherein the plate member is provided in each of the areas.

3. The electronic circuit board according to claim 1, comprising:
a positioning structure for positioning.

4. The electronic circuit board according to claim 1, wherein devices that output electromagnetic waves, devices that sense electromagnetic waves, devices that output and sense electromagnetic waves, or devices that output electromagnetic waves and devices that sense electromagnetic waves are mounted on the wiring board.

5. The electronic circuit board according to claim 4, wherein a plurality of devices that is included in the devices mounted on the wiring board and is capable of outputting light is configured to output light sequentially in a longitudinal direction.

6. The electronic circuit board according to claim 1, wherein wires are provided in a longitudinal direction of the areas.

7. The electronic circuit board according to claim 6, wherein the wires of the respective areas are connected with each other.

8. The electronic circuit board according to claim 1, wherein the plate member includes a metal.

9. A base member comprising:
a curved surface on which a positioning structure for positioning the electronic circuit board according to claim 1 is formed and the electronic circuit board is to be attached.

10. The base member according to claim 9, wherein a groove to which the plate member fits is formed as the positioning structure.

11. Electronic equipment comprising:
the electronic circuit board according to claim 1; and
the base member according to which the electronic circuit board is attached.

12. The electronic equipment according to claim 11, further comprising:
an imaging element having pixels that are to be scanned one line at a time, wherein
the electronic circuit board and the imaging element are arranged such that the longitudinal direction of the areas, and lines along which the pixels are scanned become approximately orthogonal.

13. An electronic equipment manufacturing method comprising:
sandwiching and fixing end sections of the plate member of the electronic circuit board according to claim 1 by using jigs, pressing the electronic circuit board against a curved surface corresponding to a curved surface of a base member, and deforming the electronic circuit board; and
attaching the electronic circuit board after the deformation to the curved surface of the base member.

14. An electronic circuit board manufacturing method comprising:
providing, in a plurality of areas that is long in one direction and is formed on a deformable wiring board such that the plurality of areas is partially continuous with each other, a deformable plate-like plate member that is more rigid than the wiring board.
